(19) United States
(12) Patent Application Publication
(10) Pub. No.: US 2017/0018600 A1
(43) Pub. Date: Jan. 19, 2017

(54) ORGANIC LIGHT-EMITTING DISPLAY DEVICE

(71) Applicant: Samsung Display Co., Ltd., Yongin-City (KR)

(72) Inventors: Naoyuki Ito, Yongin-City (KR); Seulong Kim, Yongin-City (KR); Younsun Kim, Yongin-City (KR); Dongwoo Shin, Yongin-City (KR); Sunghun Lee, Yongin-City (KR); Jungsub Lee, Yongin-City (KR); Changwoong Chu, Yongin-City (KR)

(21) Appl. No.: 15/132,946

(22) Filed: Apr. 19, 2016

(30) Foreign Application Priority Data
Jul. 13, 2015 (KR) 10-2015-0099221

(51) Int. Cl. H01L 27/32

(52) U.S. Cl. CPC H01L 27/3213; H01L 27/3218; H01L 2251/5376; H01L 51/5016

(57) ABSTRACT

An organic light-emitting display device having widened color gamut is disclosed. The organic light-emitting display device comprises a first sub-pixel, a second sub-pixel, a third sub-pixel, and a fourth sub-pixel, wherein the first sub-pixel comprises a first emission layer that emits a first color light, the second sub-pixel comprises a second emission layer that emits a second color light, the third sub-pixel comprises a third emission layer that emits a third color light, and the fourth sub-pixel comprises a fourth emission layer that emits a fourth color light; the first color light, the second color light, the third color light, and the fourth color light are different from each other; at least one emission layer of the first emission layer, the second emission layer, the third emission layer, and the fourth emission layer emits delayed fluorescence.

### CLAIM OF PRIORITY

This application makes reference to, incorporates the same herein, and claims all benefits accruing under 35 U.S.C. §119 from an application for an ORGANIC LIGHT-EMITTING DEVICE earlier filed in the Korean Intellectual Property Office on Jul. 13, 2015, and there duly assigned Korean Patent Application No. 10-2015-0099221.

### BACKGROUND OF THE INVENTION

Field of the Invention

One or more exemplary embodiments relate to an organic light-emitting display device.

Description of the Related Art

Organic light-emitting display devices have wide viewing angles, high contrast ratios, short response times, and low power consumption, and thus application ranges thereof are expanded from personal portable devices, such as a MP3 player or a mobile phone, to a television (TV).

Organic light-emitting display devices are characterized as self-emitting devices, and are different from liquid crystal display devices in terms of requiring no additional light source. Thus, the organic light-emitting display devices may have reduced thickness and weight.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

### SUMMARY OF THE INVENTION

One or more exemplary embodiments include an organic light-emitting display device.

Additional aspects will be set forth in part in the description which follows and, in part, will be apparent from the description, or may be learned by practice of the presented embodiments.

According to one or more exemplary embodiments, an organic light-emitting display device includes a pixel including a first sub-pixel, a second sub-pixel, a third sub-pixel, and a fourth sub-pixel,

wherein the first sub-pixel includes first emission layer that emits a first color light, the second sub-pixel includes a second emission layer that emits a second color light, the third sub-pixel includes a third emission layer that emits a third color light, and the fourth sub-pixel includes a fourth emission layer that emits a fourth color light;

the first color light, the second color light, the third color light, and the fourth color light are different from each other; and

at least one emission layer of the first emission layer, the second emission layer, the third emission layer, and the fourth emission layer emits delayed fluorescence.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1A is a plan view schematically illustrating a structure of a pixel of an organic light-emitting display device according to an exemplary embodiment of the present inventive concept, and FIG. 1B is a plan view schematically illustrating a structure of a pixel of an organic light-emitting display device according to another exemplary embodiment of the present inventive concept;

FIG. 2 is a cross-sectional view schematically illustrating a structure of a pixel of an organic light-emitting display device according to an exemplary embodiment of the present inventive concept;

FIG. 3 is plan view schematically illustrating a structure of a pixel of an organic light-emitting display device according to another exemplary embodiment of the present inventive concept;

FIG. 4 is a plan view schematically illustrating a structure of a pixel of an organic light-emitting display device according to another exemplary embodiment of the present inventive concept; and

FIG. 5 is a diagram showing CIE color coordinates of a pixel including a red sub-pixel, a green sub-pixel, and a blue sub-pixel.

FIG. 6 is a diagram showing CIE color coordinates of a pixel including a red sub-pixel, a green sub-pixel, a blue sub-pixel, and a yellow sub-pixel.

### DETAILED DESCRIPTION OF THE INVENTION

Reference will now be made in detail to exemplary embodiments, examples of which are illustrated in the accompanying drawings, wherein like reference numerals refer to like elements throughout, and thus their description will be omitted. In this regard, the present exemplary embodiments may have different forms and should not be construed as being limited to the descriptions set forth herein. Accordingly, the exemplary embodiments are merely described below, by referring to the figures, to explain aspects of the present description. Expressions such as “at least one of,” when preceding a list of elements, modify the entire list of elements and do not modify the individual elements of the list.

While such terms as “first,” “second,” etc., may be used to describe various components, such components must not be limited to the above terms. The above terms are used only to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

Organic light-emitting display devices have wide viewing angles, high contrast ratios, short response times, and low power consumption, and thus application ranges thereof are expanded from personal portable devices, such as a MP3 player or a mobile phone, to a television (TV).

Organic light-emitting display devices are characterized as self-emitting devices, and are different from liquid crystal display devices in terms of requiring no additional light source. Thus, the organic light-emitting display devices may have reduced thickness and weight.

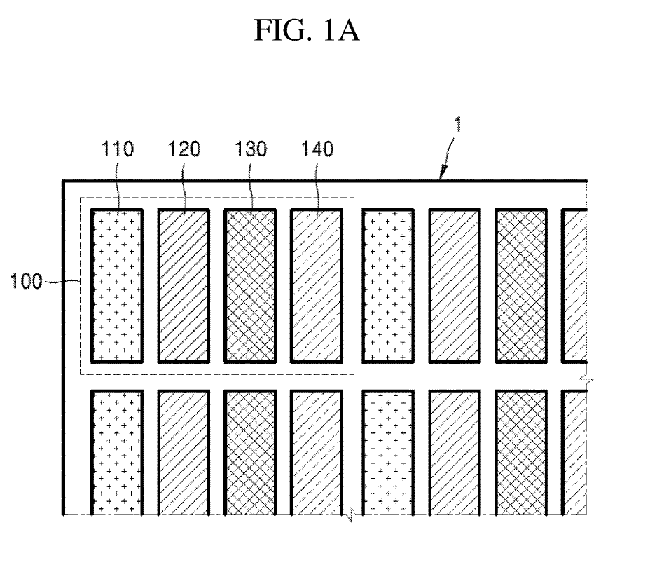

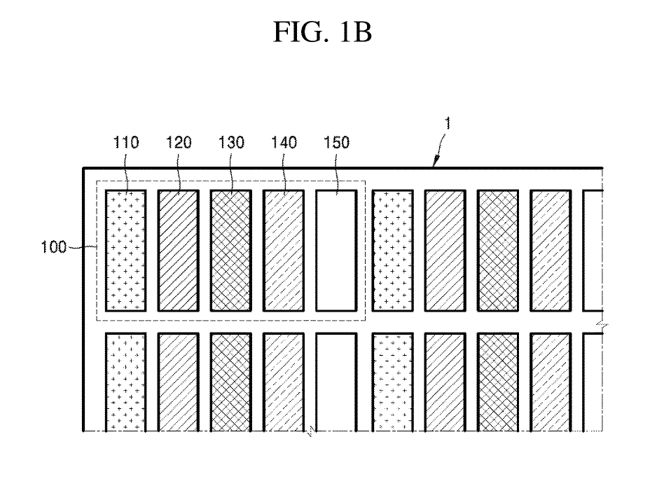

FIG. 1A is a view schematically illustrating a plane structure of a pixel 100 of an organic light-emitting display device 1 according to an exemplary embodiment of the present inventive concept. The organic light-emitting display device 1 may be prepared as a stripe type.

The organic light-emitting display device 1 includes the pixel 100 including a first sub-pixel 110, a second sub-pixel 120, a third sub-pixel 130, and a fourth sub-pixel 140, wherein the first sub-pixel 110 includes a first emission layer that emits a first color light, the second sub-pixel 120 includes a second emission layer that emits a second color light, the third sub-pixel 130 includes a third emission layer that emits a third color light, and the fourth sub-pixel 140 includes a fourth emission layer that emits a fourth color light; the first color light, the second color light, the third color light, and the fourth color light are different from each other; and at least one emission layer of the first emission layer, the second emission layer, the third emission layer, and the fourth emission layer emits delayed fluorescence.

For example, the at least one emission layer that emits delayed fluorescence may also simultaneously emit fluorescence, but the embodiment is not limited thereto.

In an exemplary embodiment, the at least one emission layer that emits delayed fluorescence may include a first material and a second material, wherein the first material may be a host and the second material may be a dopant. Here, the dopant refers to a compound that emits light.

For example, the dopant may have an energy gap ΔST (Dopant) satisfying Equation 1 below, but the embodiment is not limited thereto:

ΔST(Dopant)=Eg_{S}(Dopant)−Eg_{T}(Dopant)≦0.3 eV <Equation 1>

In Equation 1,

Eg_{S} (Dopant) indicates an excited singlet energy of the dopant, and

Eg_{T} (Dopant) indicates an excited triplet energy of the dopant.

When a compound having a small ΔST is used, intersystem crossing may be generated at a low temperature (e.g., room temperature). Thus, when a compound having a small energy gap ΔST is used and a rate of emitting delayed phosphorescence increases, an organic light-emitting display device may have improved efficiency.

In another exemplary embodiment, the dopant may have an energy gap ΔST (Dopant) satisfying Equation 1-1 below, but the embodiment is not limited thereto:

0 eV<ΔST(Dopant)<0.3 eV. <Equation 1-1>

In another exemplary embodiment, the dopant may have an energy gap ΔST (Dopant) satisfying Equation 1-2, but the embodiment is not limited thereto:

0 eV<ΔST(Dopant)<0.2 eV. <Equation 1-2>

For example, the dopant may have an energy gap ΔST (Dopant) satisfying Equation 2 below, but the embodiment is not limited thereto:

ΔST(Host)=Eg_{S}(Host)−Eg_{T}(Host)<0.3 eV <Equation 2>

In Equation 2, Eg_{S} (Host) indicates a singlet energy of the dopant, and Eg_{T} (Host) indicates a triplet energy of the dopant.

For example, at least one of the excited singlet energy of the host and the excited triplet energy of the host may be greater than at least one of the excited singlet energy of the dopant and the excited triplet energy of the dopant, but the embodiment is not limited thereto.

In another exemplary embodiment, the excited singlet energy of the host, the excited triplet energy of the host, the excited singlet energy of the dopant, and the excited triplet energy of the dopant may each independently satisfy one of Equations 2 and 3, but the embodiment is not limited thereto:

Eg_{S}(Host)>Eg_{S}(Dopant) <Equation 2>

Eg_{T}(Host)>Eg_{T}(Dopant) <Equation 3>

In Equations 2 and 3,

Eg_{S} (Host) indicates an excited singlet energy of the host,

Eg_{S} (Dopant) indicates an excited singlet energy of the dopant,

Eg_{T} (Host) indicates an excited triplet energy of the host, and

Eg_{T} (Dopant) indicates an excited triplet energy of the dopant.

For example, the host is capable of transporting holes and electrons, and may be used as a material that prevents light of the emission layer from being transformed in a long wavelength. In addition, the host may have a high glass transition temperature.

In another exemplary embodiment, the host may be selected from compounds below, but the host is not limited thereto:

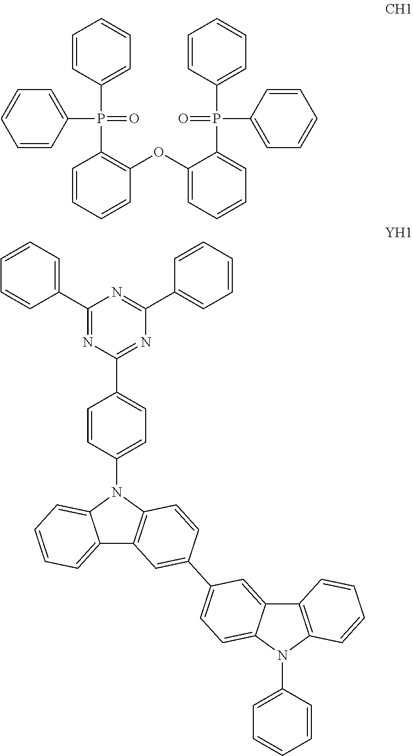

The dopant may be present in the emission layer in an amount of about 0.1 vol % or greater, about 1 vol % or greater, about 50 vol % or less, about 20 vol % or less, or about 10 vol % or less.

For example, the dopant may be a carbazole derivative, a bis-carbazole derivative, an indolocarbazole derivative, an acridine derivative, an oxazine derivative, a pyrazine derivative, a pyrimidine derivative, a triazine derivative, a dibenzofuran derivative, or a dibenzothiophene derivative, wherein such a derivative above may optionally have a substituent. Examples of the substituent may include a C6-C40 aryl group, a C2-C40 heterocyclic group, a trialkylsilyl group, a dialkylarylsilyl group, an alkyldiarylsilyl group, a triarylsilyl group, a fluorine atom, and a cyano group. The trialkylsilyl group, the dialkylarylsilyl group, the alkyldiarylsilyl group, and the triarylsilyl group may each include at least one substituent selected from a C1-C30 alkyl group and a C6-C30 aryl group. In addition, a deuterium atom may replace a hydrogen atom.

In another exemplary embodiment, the dopant may be a compound having a combined structure comprising at least one structure selected from a carbazole structure, a bis-carbazole structure, an indolocarbazole structure, and an acridine structure and at least one structure selected from an oxazine structure, a pyrazine structure, a pyrimidine structure, a triazine structure, and a dibenzofuran structure. Here, the term “combined” may be construed as being connected or linked with each other via any connecting or linking group, and examples of the connecting or linking group may include a single bond, a phenylene group, and a meta-biphenylene group.

The carbazole structure, the bis-carbazole structure, the indolocarbazole structure, the acridine structure, the oxazine structure, the pyrazine structure, the pyrimidine structure, the triazine structure, and the dibenzofuran structure may refer to cyclic structures including, as a partial structure, a carbazole, a bis-carbazole, an indolocarbazole, an acridine, an oxazine, a pyrazine, a pyrimidine, a triazine, and a dibenzofuran, respectively.

The carbazole structure, the bis-carbazole structure, the indolocarbazole structure, the acridine structure, the oxazine structure, the pyrazine structure, the pyrimidine structure, the triazine structure, and the dibenzofuran structure may optionally include a substituent. Examples of the substituent may include a C6-C40 aryl group, a C2-C40 heterocyclic group, a trialkylsilyl group, a dialkylarylsilyl group, an alkyldiarylsilyl group, a triarylsilyl group, a fluorine atom, and a cyano group. The trialkylsilyl group, the dialkylarylsilyl group, the alkyldiarylsilyl group, and the triarylsilyl group may each include at least one substituent selected from a C1-C30 alkyl group and a C6-C30 aryl group. In addition, a deuterium atom may replace a hydrogen atom.

The dopant may be in a combined form comprising a donor element and an acceptor element, and an example of the dopant may include a compound represented by one of Formulae 101 and 102:

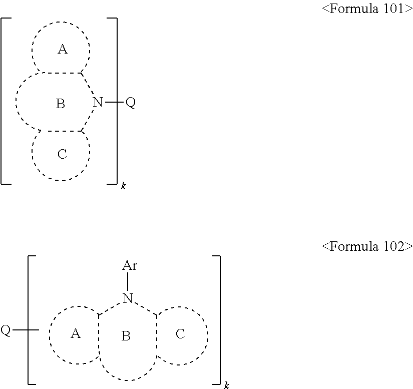

In Formulae 101 and 102,

A, B, and C may each be independently selected from a substituted or unsubstituted 5-membered ring to a substituted or unsubstituted 7-membered ring, each including at least one of a carbon atom, a nitrogen atom, an oxygen atom, a sulfur atom, and a silicon atom as a ring-forming atom,

A, B, and C may be condensed to each other, and

C may be optionally further condensed to a ring other than A and B.

In Formulae 101 and 102, Q may be selected from a monovalent or divalent C₅-C₆₀ arene and a monovalent or divalent C₂-C₆₀ heteroarene.

In Formulae 101 and 102, k may be selected from 1 and 2.

In Formula 102, Ar may be a substituted or unsubstituted aromatic hydrocarbon group.

The compound of one of Formulae 101 and 102 may be represented by one of Formulae 101A, 101B, 102A, and 102B:

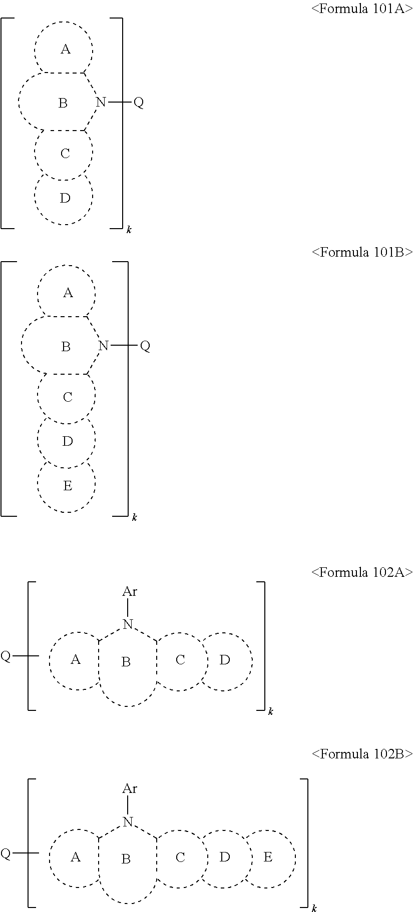

In Formulae 101A, 101B,

102A, and 102B, A, B, C, Q, Ar, and k are defined the same as those provided in connection with Formulae 101 and 102, and

D and E may each independently selected from a substituted or unsubstituted 5-membered ring to a substituted or unsubstituted 7-membered ring, each including at least one of a carbon atom, a nitrogen atom, an oxygen atom, a sulfur atom, and a silicon atom as a ring-forming atom.

The compound of Formula 101 may be represented by one of Formulae 101-1 to 101-11, but the compound of Formula 101 is not limited thereto:

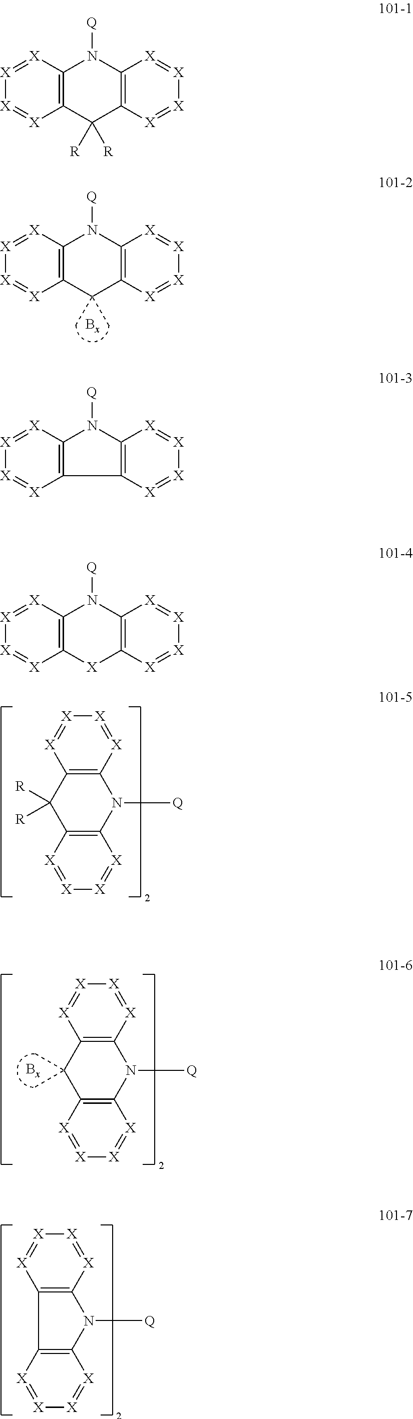

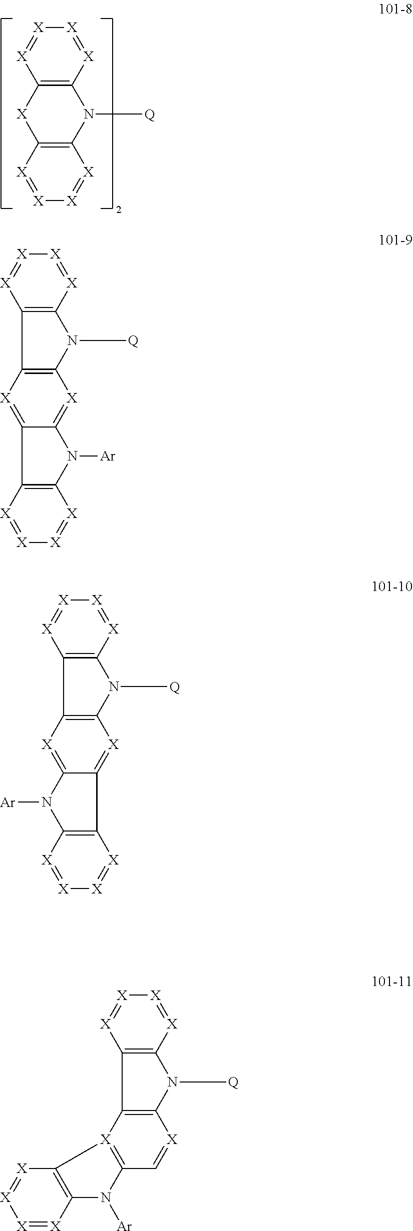

In Formulae 101-1 to 101-11, Q is defined the same as that provided in connection with Formula 101.

In Formulae 101-1 to 101-11, R may be an alkyl group, X may be selected from CH, CRₓ, O, S, and N, and Rₓ may be a substituent.

In Formulae 101-2 and 101-6, Bₓ may be selected from a 5-membered ring to a 7-membered ring, each comprising carbon atoms.

The compound of Formula 101 may be represented by one of Formulae 101-21 to 101-28, but the compound of Formula 101 is not limited thereto:

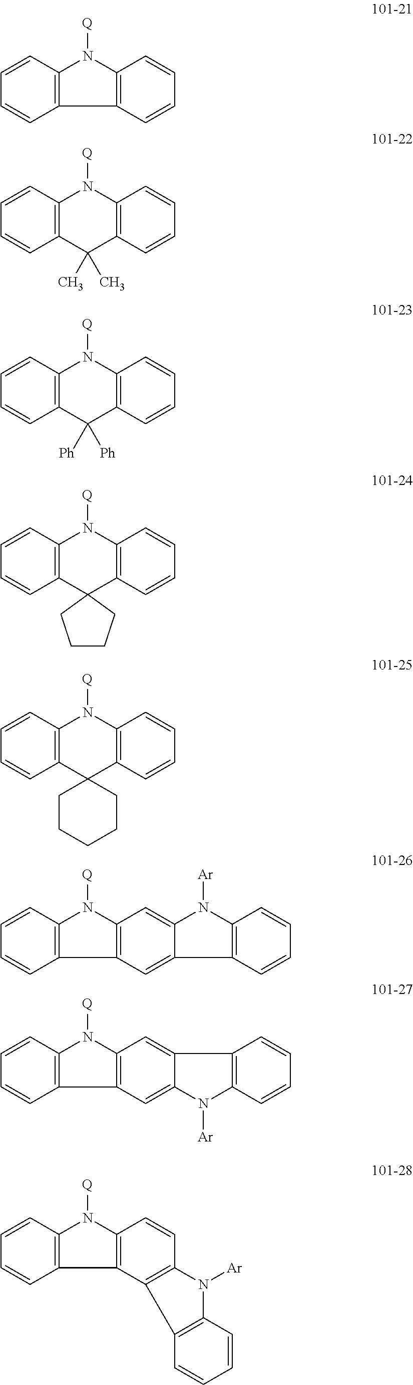

In Formulae 101-21 to 101-28, Q and Ar are defined the same as those provided in connection with Formula 101-1, and Ph is a phenyl group.

The compound of Formula 102 may be represented by one of Formulae 102-1 to 102-6, but the compound of Formula 102 is not limited thereto:

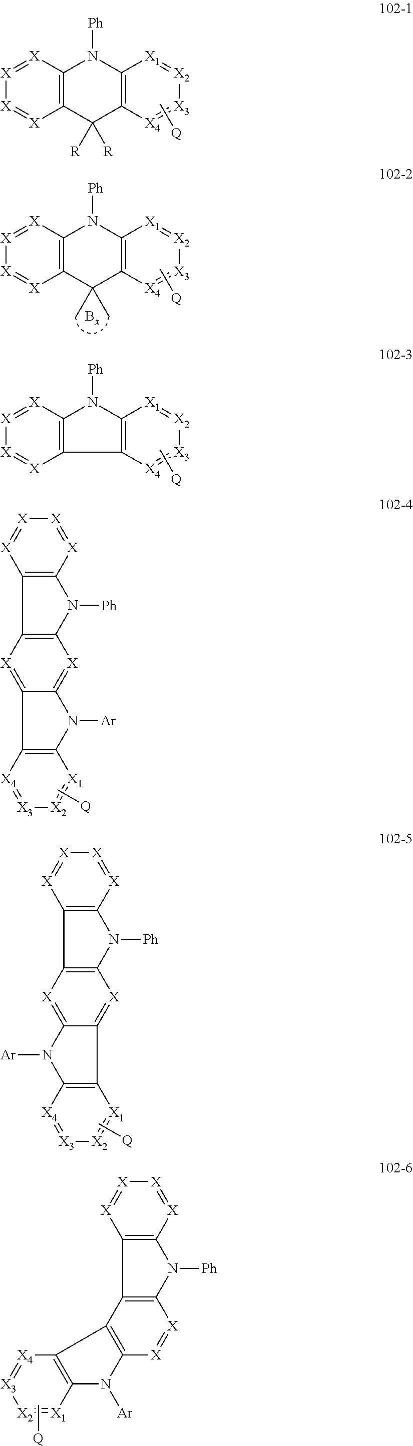

In Formulae 102-1 to 102-6, R may be an alkyl group.

In Formulae 102-1 to 102-6, X and X₁ to X₄ may each be independently selected from CH, CRₓ, and N, and Rₓ may be a substituent, wherein one of X₁ to X₄ may be a carbon atom binding to Q.

In Formulae 102-1 to 102-6, Bx may be selected from a 5-membered ring to a 7-membered ring, each comprising carbon atoms.

In Formulae 102-1 to 102-6, Ar may be an aromatic hydrocarbon group, and Ph is a phenyl group.

For example, in Formulae 102-1 to 102-6, X₁ or X₄ may be a carbon atom binding to Q.

The compound of Formula 102 may be represented by one of Formulae 102-11 to 102-20, but the compound of Formula 102 is not limited thereto:

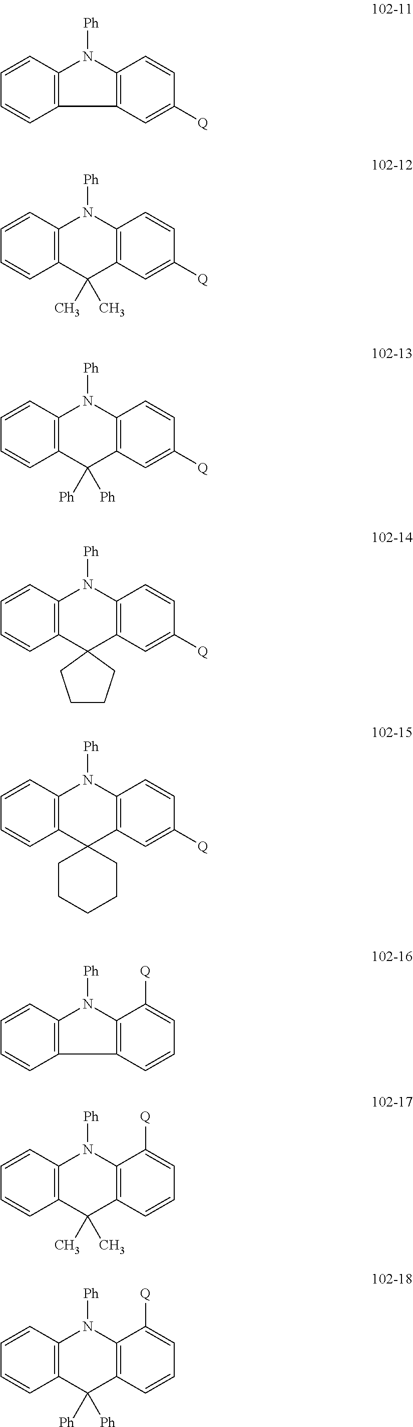

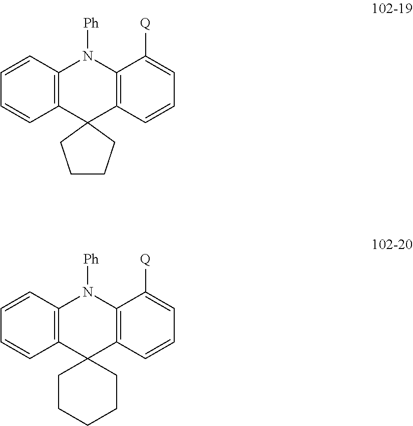

In Formulae 102-11 to 102-20, Q is defined the same as that provided in connection with Formula 102-1, and Ph is a phenyl group.

In another exemplary embodiment, the dopant may be selected from compounds below, but the dopant is not limited thereto:

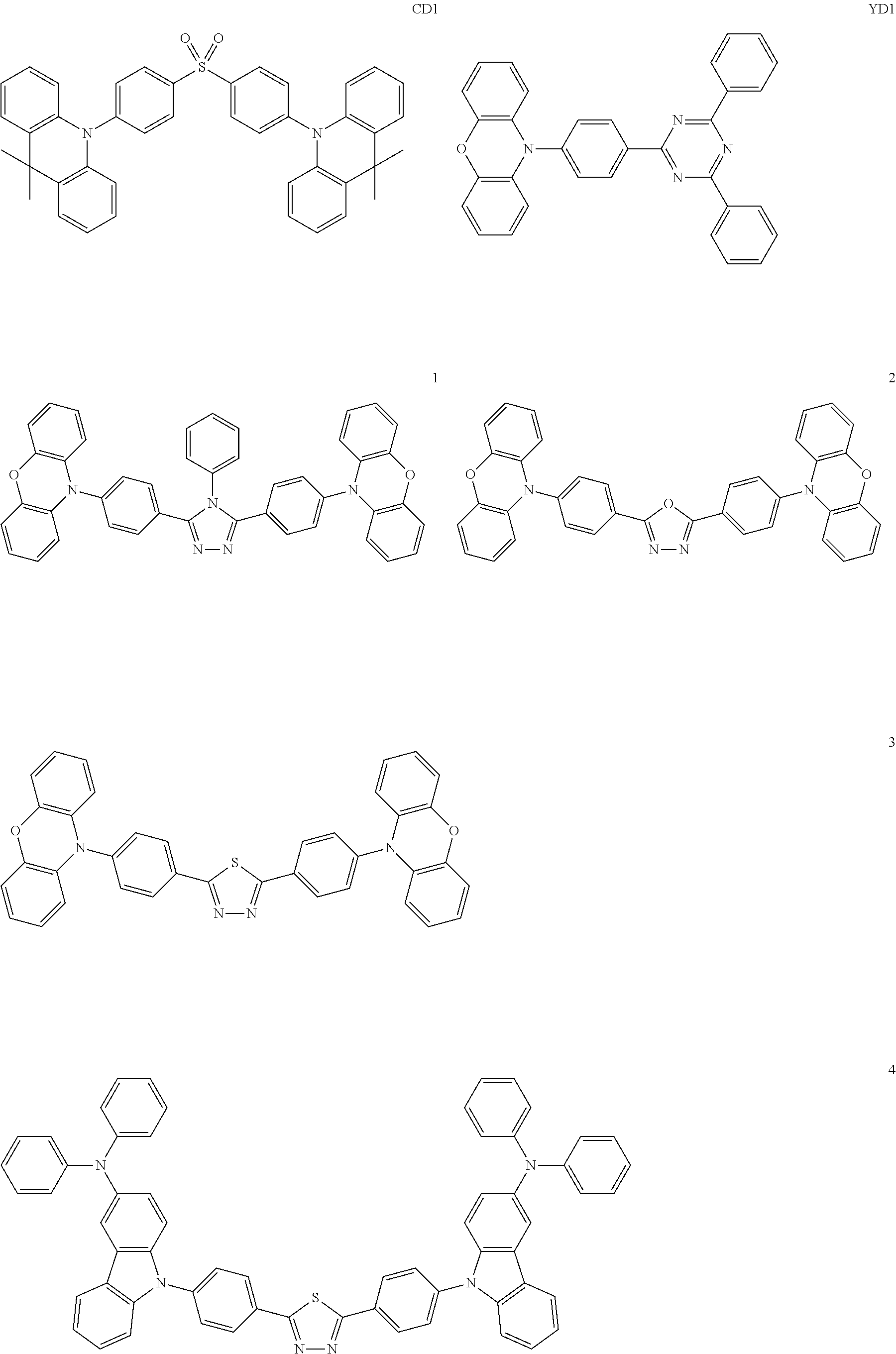

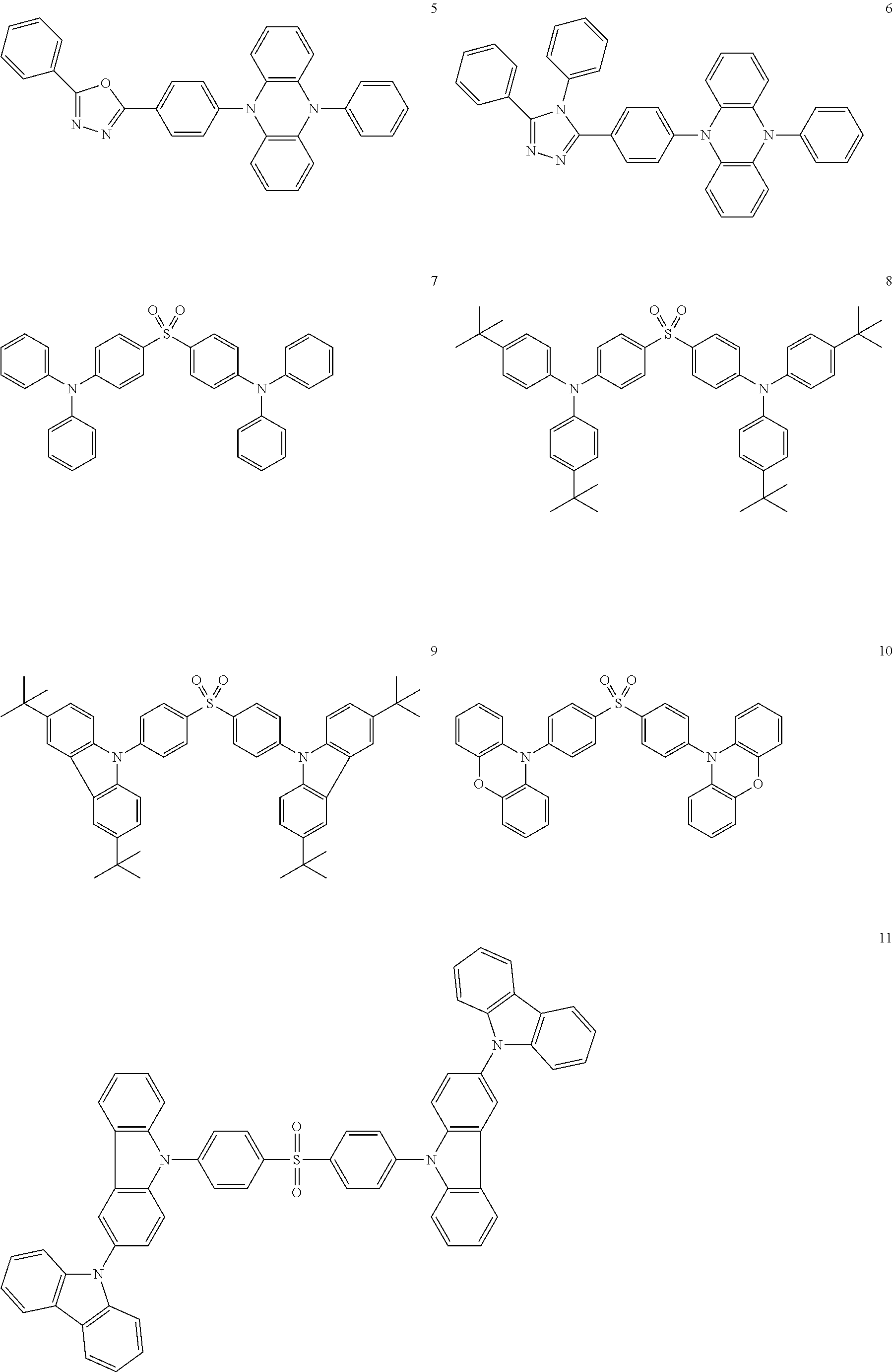

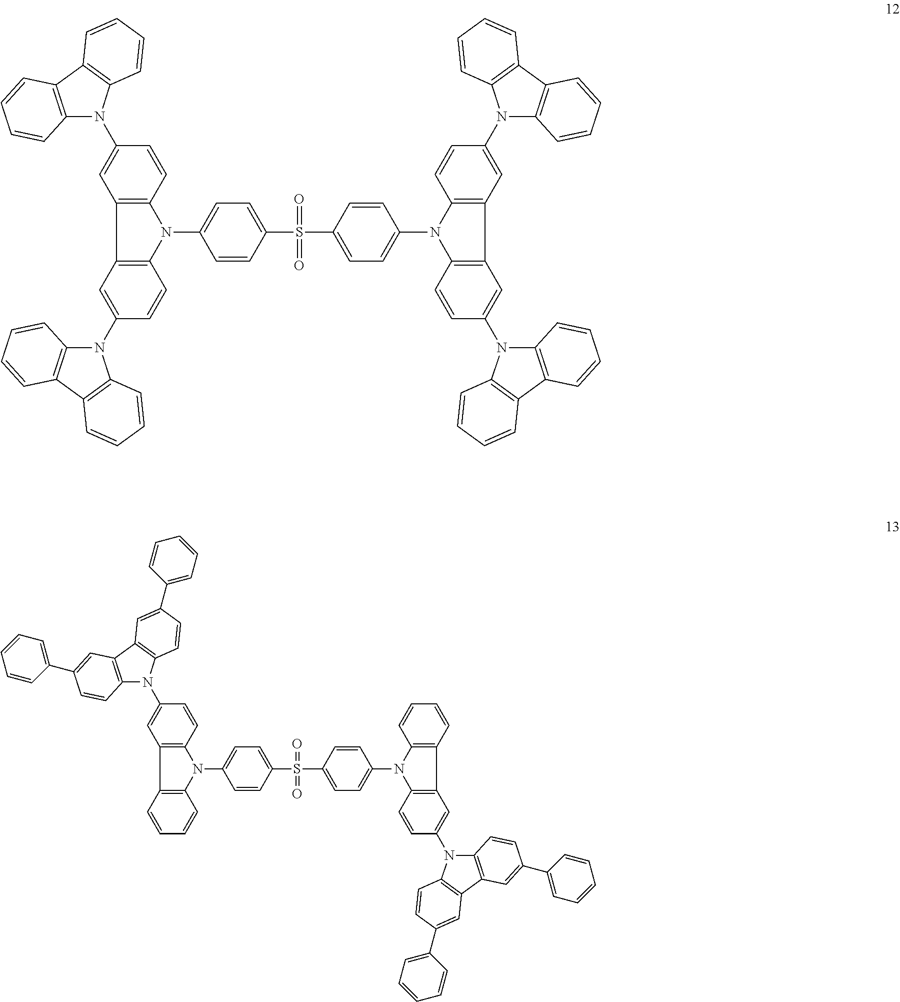 [SMILES: O=S(=O)(c1ccc(-n2c3ccc(-n4c5ccccc5c5ccccc54)cc3c3cc(-n4c5ccccc5c5ccccc54)ccc32)cc1)c1ccc(-n2c3ccc(-n4c5ccccc5c5ccccc54)cc3c3cc(-n4c5ccccc5c5ccccc54)ccc32)cc1 ; O=S(=O)(c1ccc(-n2c3ccccc3c3cc(-n4c5ccc(-c6ccccc6)cc5c5cc(-c6ccccc6)ccc54)ccc32)cc1)c1ccc(-n2c3ccccc3c3cc(-n4c5ccc(-c6ccccc6)cc5c5cc(-c6ccccc6)ccc54)ccc32)cc1]

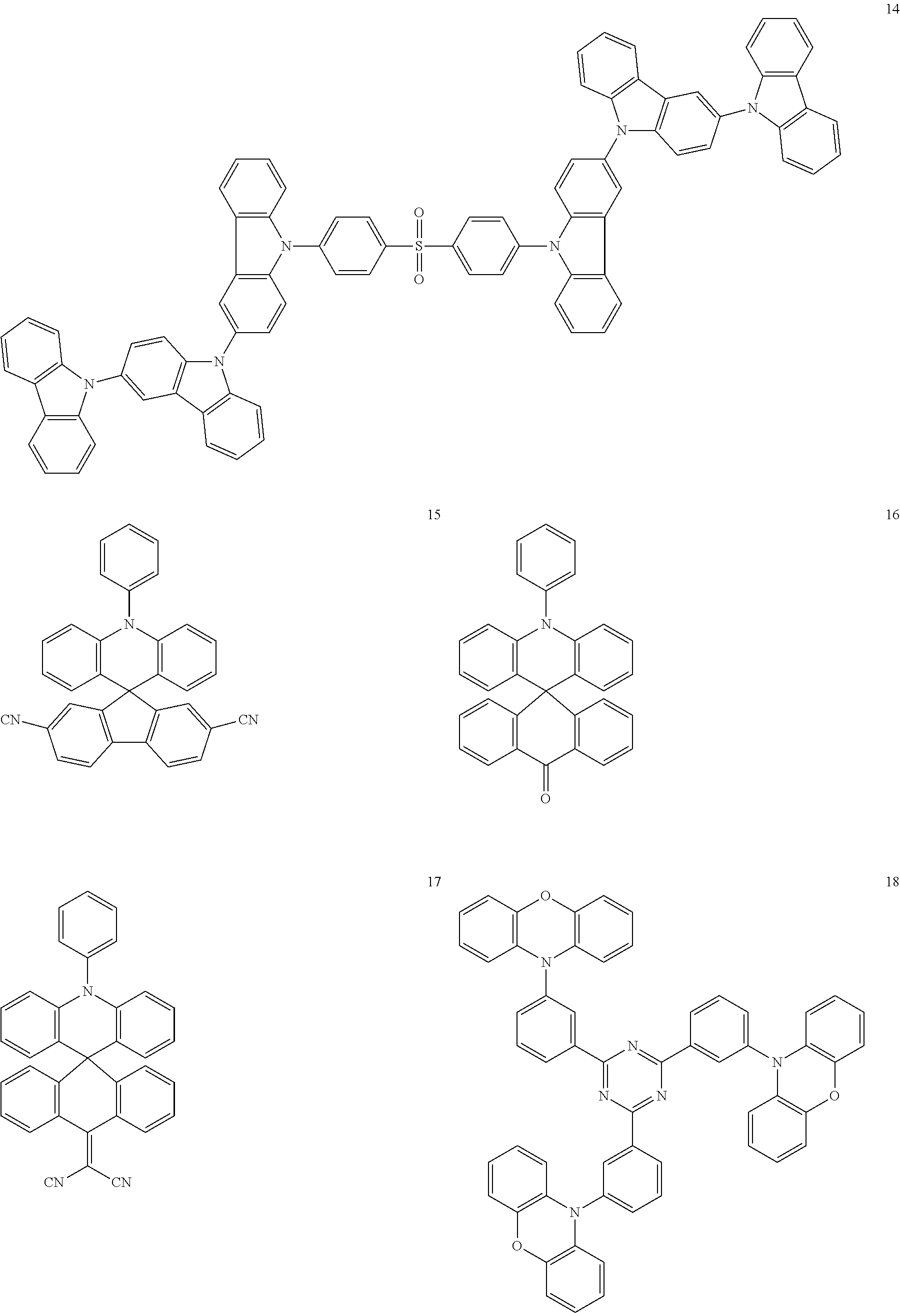

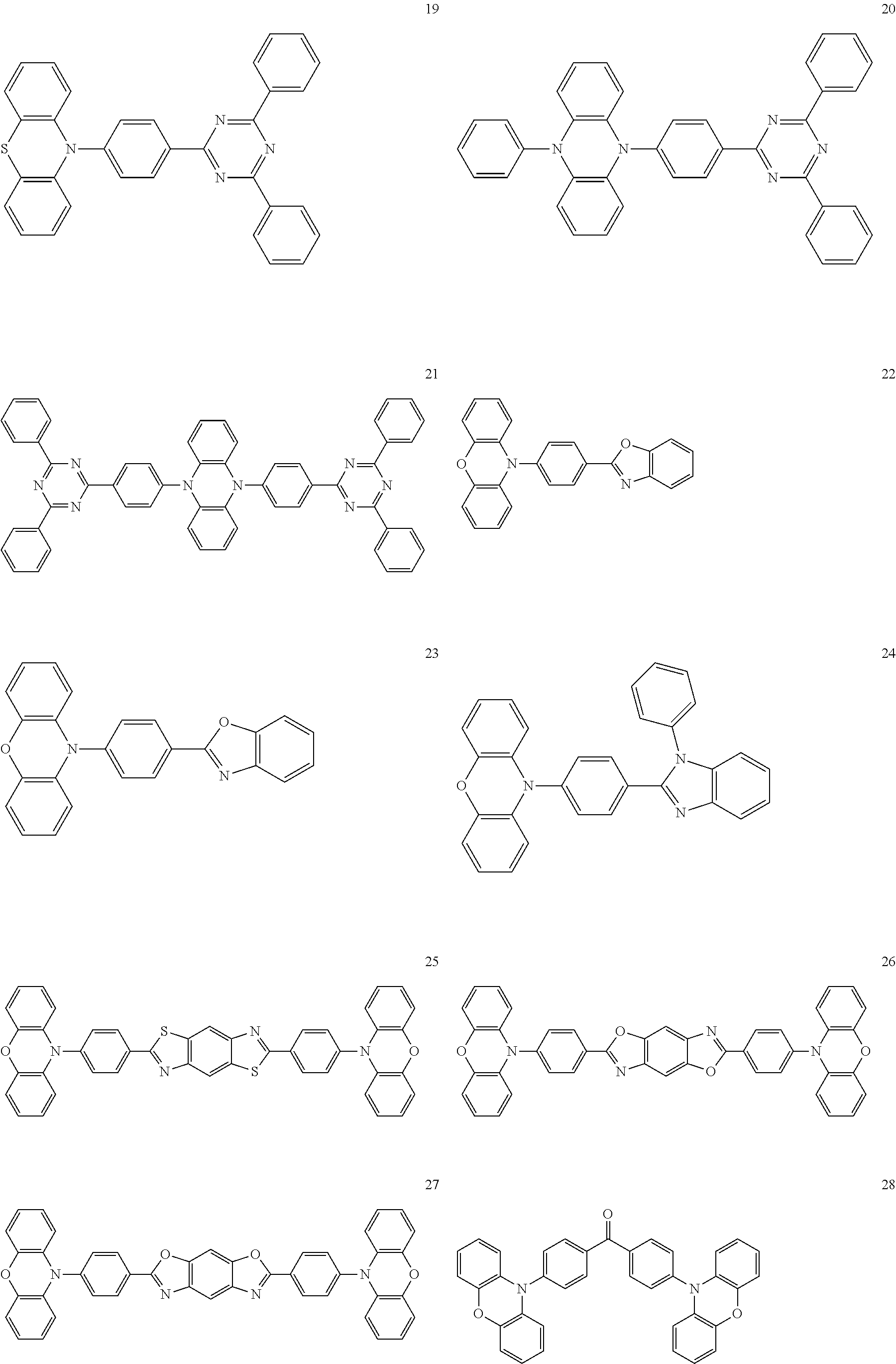

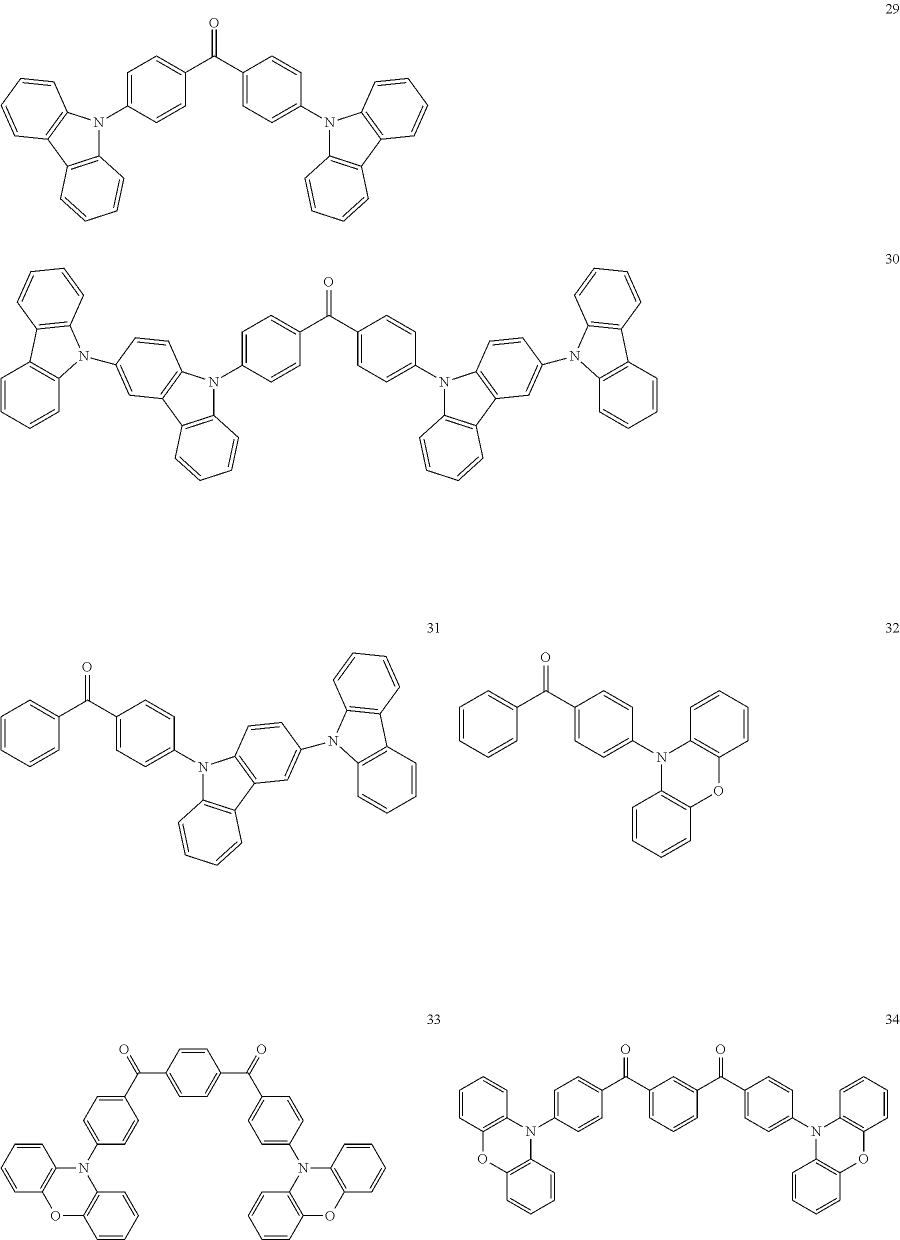 [SMILES: O=C(c1ccc(-n2c3ccccc3c3ccccc32)cc1)c1ccc(-n2c3ccccc3c3ccccc32)cc1 ; O=C(c1ccc(-n2c3ccccc3c3cc(-n4c5ccccc5c5ccccc54)ccc32)cc1)c1ccc(-n2c3ccccc3c3cc(-n4c5ccccc5c5ccccc54)ccc32)cc1 ; O=C(c1ccccc1)c1ccc(-n2c3ccccc3c3cc(-n4c5ccccc5c5ccccc54)ccc32)cc1 ; O=C(c1ccccc1)c1ccc(N2c3ccccc3Oc3ccccc32)cc1 ; O=C(c1ccc(C(=O)c2ccc(N3c4ccccc4Oc4ccccc43)cc2)cc1)c1ccc(N2c3ccccc3Oc3ccccc32)cc1 ; O=C(c1ccc(N2c3ccccc3Oc3ccccc32)cc1)c1cccc(C(=O)c2ccc(N3c4ccccc4Oc4ccccc43)cc2)c1]

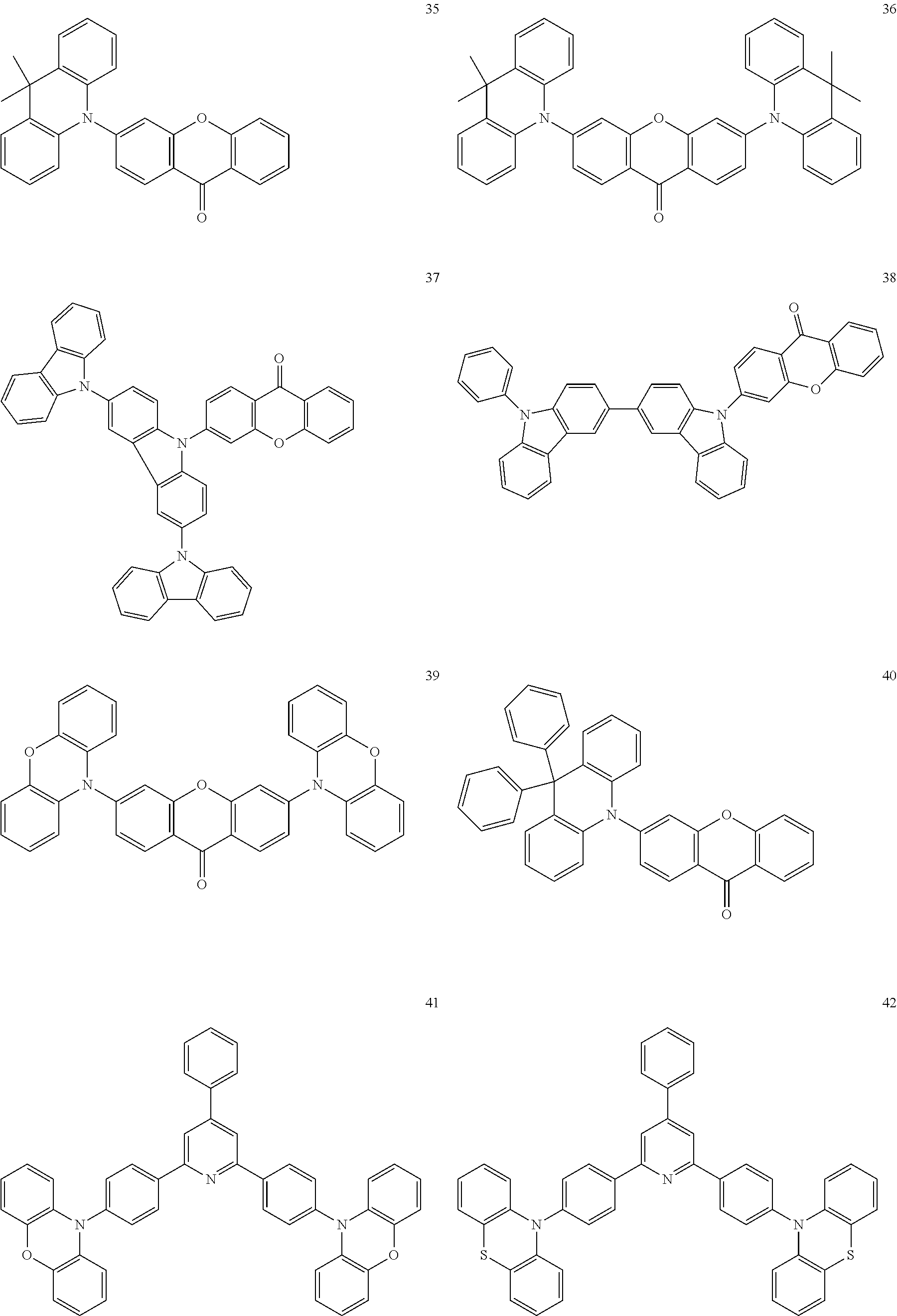

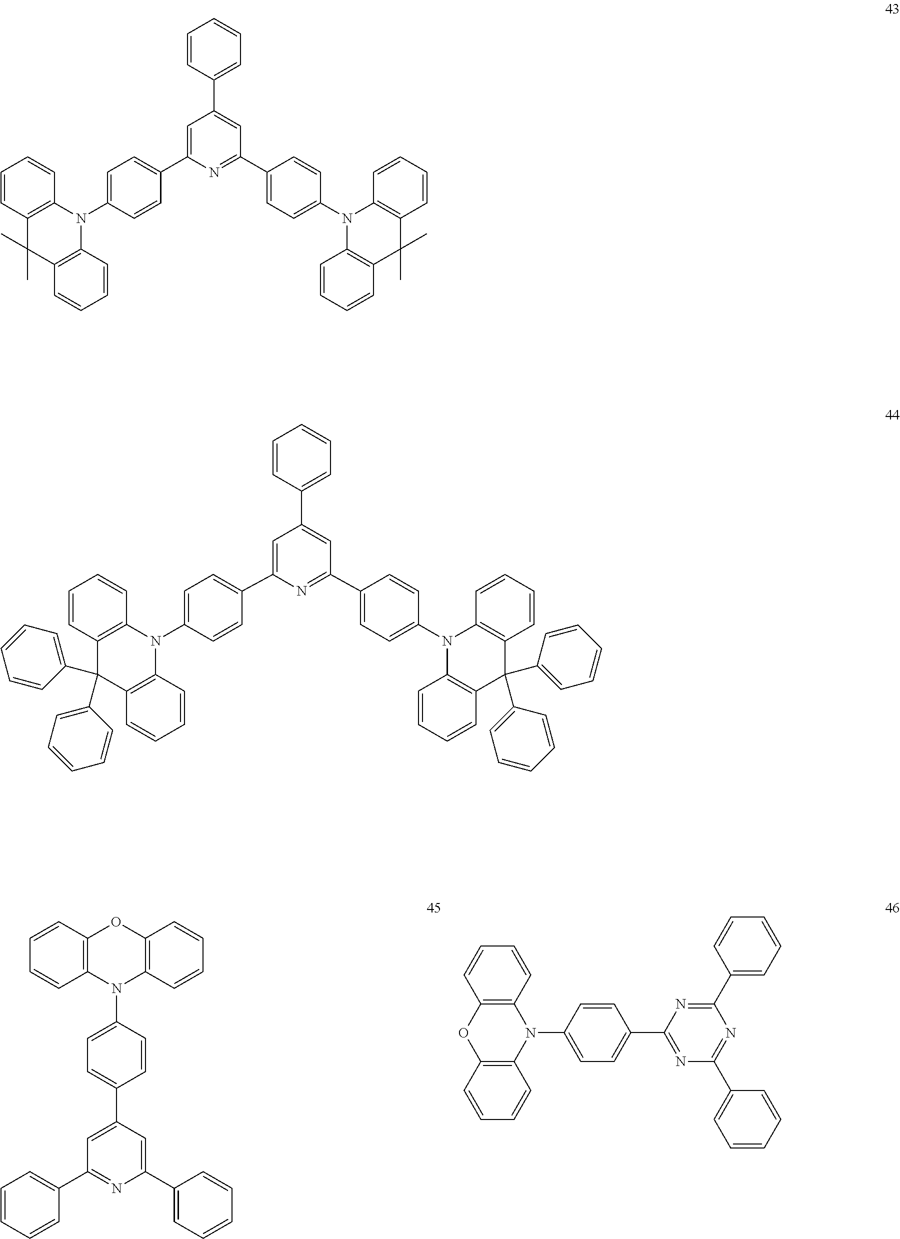 [SMILES: CC1(C)c2ccccc2N(c2ccc(-c3cc(-c4ccccc4)cc(-c4ccc(N5c6ccccc6C(C)(C)c6ccccc65)cc4)n3)cc2)c2ccccc21 ; c1ccc(-c2cc(-c3ccc(N4c5ccccc5C(c5ccccc5)(c5ccccc5)c5ccccc54)cc3)nc(-c3ccc(N4c5ccccc5C(c5ccccc5)(c5ccccc5)c5ccccc54)cc3)c2)cc1 ; c1ccc(-c2cc(-c3ccc(N4c5ccccc5Oc5ccccc54)cc3)cc(-c3ccccc3)n2)cc1 ; c1ccc(-c2nc(-c3ccccc3)nc(-c3ccc(N4c5ccccc5Oc5ccccc54)cc3)n2)cc1]

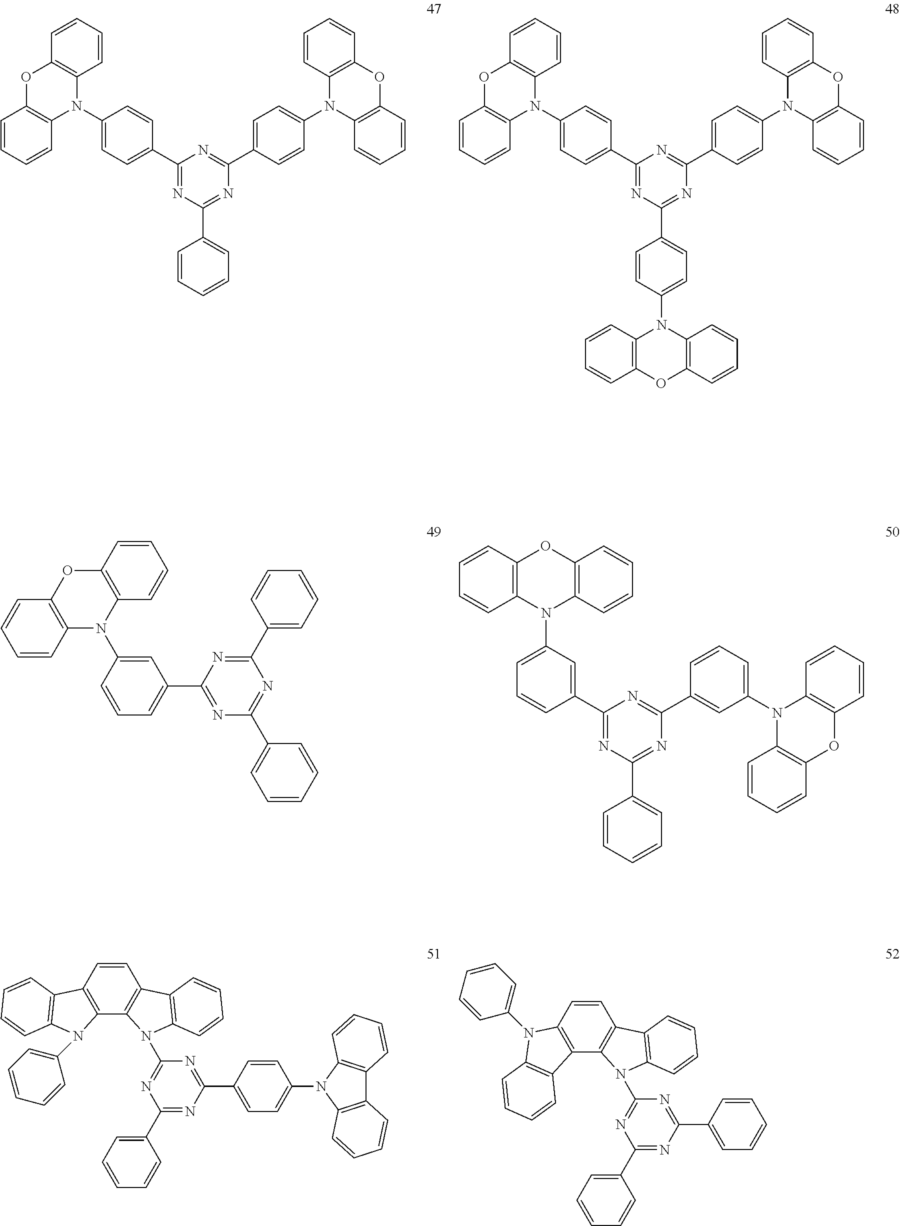

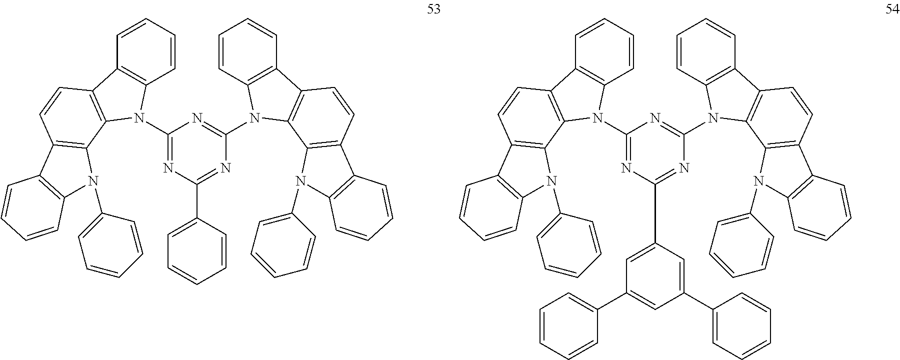 [SMILES: c1ccc(-c2nc(-n3c4ccccc4c4ccc5c6ccccc6n(-c6ccccc6)c5c43)nc(-n3c4ccccc4c4ccc5c6ccccc6n(-c6ccccc6)c5c43)n2)cc1 ; c1ccc(-c2cc(-c3ccccc3)cc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)c2)cc1]

The first color light, the second color light, the third color light, and the fourth color light may be combined with each other to emit white light.

For example, the first color light may be red color light, the second color light may be green color light, the third color light may be blue color light, and the fourth color light may be selected from yellow color light, cyan color light, and magenta color light, but the embodiment is not limited thereto.

In another exemplary embodiment, the fourth color light may be yellow color light or cyan color light, but the embodiment is not limited thereto.

In another exemplary embodiment, the fourth color light which is delayed fluorescence may be yellow color light, cyan color light, or magenta color light, but the embodiment is not limited thereto.

In another exemplary embodiment, the fourth color light which is delayed fluorescence may be yellow color light or cyan color light, but the embodiment is not limited thereto.

The yellow color light may have a maximum emission wavelength in a range of about 500 nm to about 740 nm, but the embodiment is not limited thereto. The cyan color light may have a maximum emission wavelength in a range of about 445 nm to about 560 nm, but the embodiment is not limited thereto. The magenta color light may have an emission wavelength in a range of about 445 nm to about 485 nm and about 625 nm to about 740 nm, but the embodiment is not limited thereto.

The red color light may have a maximum emission wavelength in a range of about 580 nm to about 700 nm, but the embodiment is not limited thereto. The green color light may have a maximum emission wavelength in a range of about 500 nm to about 600 nm, but the embodiment is not limited thereto. The blue color light may have a maximum emission wavelength in a range of about 400 nm to about 500 nm, but the embodiment is not limited thereto.

In an exemplary embodiment, areas of the first sub-pixel 110, the second sub-pixel 120, the third sub-pixel 130, and the fourth sub-pixel 140 may be identical to or different from each other, but the embodiment is not limited thereto.

In FIG. 1A, a structure of a pixel 100 of an organic light-emitting display device 1 in which the first sub-pixel 110, the second sub-pixel 120, the third sub-pixel 130, and the fourth sub-pixel 140 are sequentially disposed in the stated order is illustrated, but the structure is not limited thereto. For example, the pixel 100 may have a structure in which the first sub-pixel 110 and the fourth sub-pixel 140 are disposed adjacent to each other, a structure in which the second sub-pixel 120 and the fourth sub-pixel 140 are disposed adjacent to each other, or a structure in which the third sub-pixel 130 and the fourth sub-pixel 140 are disposed adjacent to each other.

FIG. 1B is a plan view schematically illustrating a structure of the pixel 100 of the organic light-emitting display device 1 according to an exemplary embodiment. The organic light-emitting display device 1 may be prepared as a stripe type. For example, the organic light-emitting display device 1 of FIG. 1B may further include a sub-pixel in addition to the organic light-emitting display device of FIG. 1A.

In an exemplary embodiment, the pixel 100 may further include a fifth sub-pixel 150. The fifth sub-pixel 150 may include a fifth emission layer that emits a fifth color light, wherein the fifth color light may be identical to or different from one of the first color light, the second color light, the third color light, and the fourth color light, but the embodiment is not limited thereto.

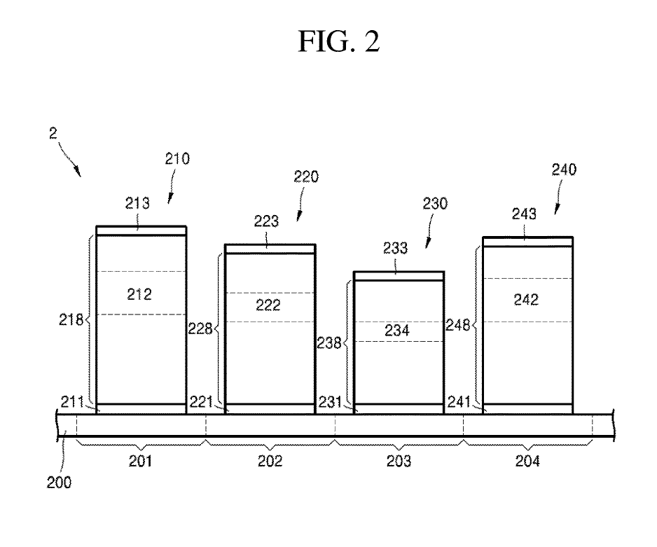

FIG. 2 is a cross-sectional view schematically illustrating a structure of a pixel of an organic light-emitting display device 2 according to an exemplary embodiment.

The organic light-emitting display device 2 may include a first sub-pixel 210, a second sub-pixel 220, a third sub-pixel 230, and a fourth sub-pixel 240.

The organic light-emitting display device 2 may include a substrate 200 including a first sub-pixel region 201, a second sub-pixel region 202, a third sub-pixel region 203, and a fourth sub-pixel region 204.

The substrate 200 may be a glass substrate or a transparent plastic substrate, each with excellent mechanical strength, thermal stability, transparency, surface smoothness, ease of handling, and water repellency.

The first sub-pixel 210 may be disposed on the first sub-pixel region 201, the second sub-pixel 220 may be disposed on the second sub-pixel region 202, the third sub-pixel 230 may be disposed on the third sub-pixel region 203, and the fourth sub-pixel 240 may be disposed on the fourth sub-pixel region 204.

The first sub-pixel 210, the second sub-pixel 220, the third sub-pixel 230, and the fourth sub-pixel 240 may include first electrodes 211, 221, 231, and 241, and second electrodes 213, 223, 233, and 243, respectively, wherein the second electrodes 213, 223, 233, and 243 face opposite to the first electrodes 211, 221, 231, and 241.

The first electrodes 211, 221, 231, and 241 may be formed by, for example, depositing or sputtering a material for forming the first electrodes 211, 221, 231, and 241 on the substrate 200. When the first electrodes 211, 221, 231, and 241 are anodes, the material for forming the first electrodes 211, 221, 231, and 241 may be selected from materials with a high work function to facilitate hole injection. The first electrodes 211, 221, 231, and 241 may be reflective electrodes, semi-transmissive electrodes, or transmissive electrodes. The material for forming the first electrodes 211, 221, 231, and 241 may be indium tin oxide (ITO), indium zinc oxide (IZO), tin oxide (SnO₂), or zinc oxide (ZnO), each with transparency and excellent conductivity. Alternatively, to form the first electrodes 211, 221, 231, and 241 as semi-transmissive electrodes or reflective electrodes, the material for forming the first electrodes 211, 221, 231, and 241 may be at least one selected from magnesium (Mg), aluminum (Al), aluminum-lithium (Al—Li), calcium (Ca), magnesium-indium (Mg—In), and magnesium-silver (Mg—Ag).

The first electrodes 211, 221, 231, and 241 may have a single-layer structure or a multi-layer structure including a plurality of layers. For example, the first electrodes 211, 221, 231, and 241 may have a triple-layered structure of ITO/Ag/ITO, but the structure is not limited thereto.

The second electrodes 213, 223, 233, and 243 may be cathodes, which are electron injection electrodes. Here, a material for forming the second electrodes 213, 223, 233, and 243 may be metals having a low work function, alloys, electrically conductive compounds, or mixtures thereof. Examples of the second electrodes 213, 223, 233, and 243 are Li, Mg, Al, Al—Li, Ca, Mg—In, and Mg—Ag. Alternatively, the material for forming second electrodes 213, 223, 233, and 243 may be ITO or IZO. The second electrodes 213, 223, 233, and 243 may be reflective electrodes, semi-transmissive electrodes, or transmissive electrodes.

Organic layers 218, 228, 238, and 248 may be disposed between the first electrodes 211, 221, 231, and 241 and the second electrodes 213, 223, 233, and 243.

The first sub-pixel 210 may include a first emission layer 212 that emits a first color light, the second sub-pixel 220 may include a second emission layer 222 that emits a second color light, the third sub-pixel 230 may include a third emission layer 232 that emits a third color light, and the fourth sub-pixel 240 may include a fourth emission layer 242 that emits a fourth color light.

The organic layers 218, 228, 238, and 248 may further include hole transport regions between the first electrodes 211, 221, 231, and 241 and the first to fourth emission layers 212, 222, 232, and 242. The organic layers 218, 228, 238, and 248 may also further include electron transport regions between the first to fourth emission layers 212, 222, 232, and 242 to the second electrodes 213, 223, 233, and 243.

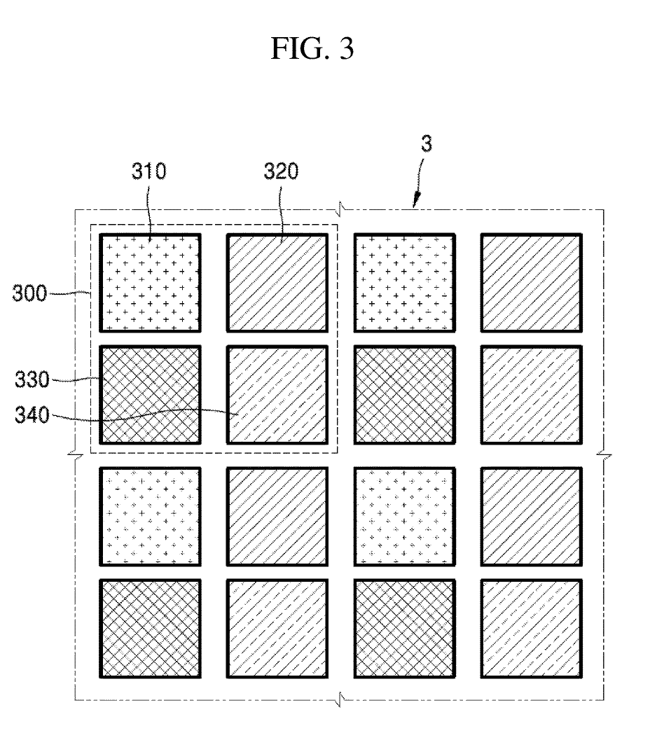

FIG. 3 is a plan view schematically illustrating a structure of a pixel 300 of an organic light-emitting display device 3 according to another exemplary embodiment. The organic light-emitting display device 3 may be prepared as a square type.

The organic light-emitting display device 3 includes the pixel 300 including a first sub-pixel 310, a second sub-pixel 320, a third sub-pixel 330, and a fourth sub-pixel 340, wherein the first sub-pixel 310 includes a first emission layer that emits a first color light, the second sub-pixel 320 includes a second emission layer that emits a second color light, the third sub-pixel 330 includes a third emission layer that emits a third color light, and the fourth sub-pixel 340 includes a fourth emission layer that emits a fourth color light; the first color light, the second color light, the third color light, and the fourth color light may be different from each other; and at least one emission layer of the first to fourth emission layers may emit delayed fluorescence.

In an exemplary embodiment, the first color light, the second color light, the third color light, and the fourth color light of the pixel 300 may be combined with each other to emit white light.

In an exemplary embodiment, only one emission layer of the first to fourth emission layers may include the organometallic compound. For example, only the fourth emission layer may include the organometallic compound, but the embodiment is not limited thereto.

In an exemplary embodiment, the first color light may be red color light, the second color light may be green color light, the third color light may be blue color light, and the fourth color light may be selected from yellow color light, cyan color light, and magenta color light, but the embodiment is not limited thereto.

In another exemplary embodiment, the fourth color light may be yellow color light or cyan color light, but the embodiment is not limited thereto.

In another exemplary embodiment, the fourth color light which is delayed fluorescence may be yellow color light, cyan color light, or magenta color light, but the embodiment is not limited thereto.

In another exemplary embodiment, the fourth color light which is delayed fluorescence may be yellow color light or cyan color light, but the embodiment is not limited thereto.

The yellow color light may have a maximum emission wavelength in a range of about 500 nm to about 740 mm, but the embodiment is not limited thereto. The cyan color light may have a maximum emission wavelength in a range of about 445 nm to about 560 nm, but the embodiment is not limited thereto. The magenta color light may have an emission wavelength in a range of about 445 nm to about 485 nm and about 625 nm to about 740 nm, but the embodiment is not limited thereto.

The red color light may have a maximum emission wavelength in a range of about 580 nm to about 700 nm, but the embodiment is not limited thereto. The green color light may have a maximum emission wavelength in a range of about 500 nm to about 600 nm, but the embodiment is not limited thereto. The blue color light may have a maximum emission wavelength in a range of about 400 nm to about 500 nm, but the embodiment is not limited thereto.

In an exemplary embodiment, areas of the first sub-pixel 310, the second sub-pixel 320, the third sub-pixel 330, and the fourth sub-pixel 340 may be identical to or different from each other, but the embodiment is not limited thereto.

In FIG. 3, a structure of the pixel 300 in which the first sub-pixel 310 is disposed adjacent to the second sub-pixel 320 and the third sub-pixel 330, the second sub-pixel 320 is disposed adjacent to the first sub-pixel 310 and the fourth sub-pixel 340, the third sub-pixel 330 is disposed adjacent to the first sub-pixel 310 and the fourth sub-pixel 340, and the fourth sub-pixel 340 is disposed adjacent to the second sub-pixel 320 and the third sub-pixel 330 is illustrated, but the structure is not limited thereto. For example, the pixel 300 may have a structure in which the first sub-pixel 310 and the fourth sub-pixel 340 are disposed adjacent to each other.

In an exemplary embodiment, the pixel 300 may further include a fifth sub-pixel. The fifth sub-pixel may include a fifth emission layer that emits a fifth color light, wherein the fifth color light may be identical to or different from one of the first color light, the second color light, the third color light, and the fourth color light, but the embodiment is not limited thereto.

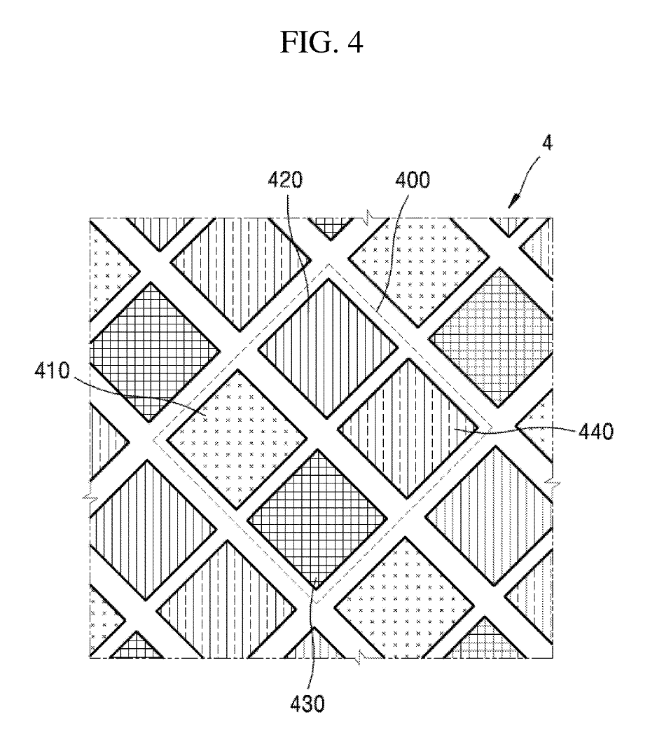

FIG. 4 is a plan view schematically illustrating a structure of a pixel 400 of an organic light-emitting display device 4 according to another exemplary embodiment. The organic light-emitting display device 4 may be prepared as a pentile type.

The organic light-emitting display device 4 includes the pixel 400 including a first sub-pixel 410, a second sub-pixel 420, a third sub-pixel 430, and a fourth sub-pixel 440, wherein the first sub-pixel 410 includes a first emission layer that emits a first color light, the second sub-pixel 420 includes a second emission layer that emits a second color light, the third sub-pixel 430 includes a third emission layer that emits a third color light, the fourth sub-pixel 440 includes a fourth emission layer that emits a fourth color light; the first color light, the second color light, the third color light, and the fourth color light may be different from each other; and at least one emission layer of the first to fourth emission layers may include the organometallic compound of Formula 1.

In an exemplary embodiment, the first color light, the second color light, the third color light, and the fourth color light of the pixel 400 may be combined with each other to emit white light.

In an exemplary embodiment, only one emission layer of the first to fourth emission layers may include the organometallic compound. For example, only the fourth emission layer may include the organometallic compound, but the embodiment is not limited thereto.

In an exemplary embodiment, the first color light may be red color light, the second color light may be green color light, the third color light may be blue color light, and the fourth color light may be selected from yellow color light, cyan color light, and magenta color light, but the embodiment is not limited thereto.

In another exemplary embodiment, the fourth color light may be yellow color light or cyan color light, but the embodiment is not limited thereto.

In another exemplary embodiment, the fourth color light which is delayed fluorescence may be yellow color light, cyan color light, or magenta color light, but the embodiment is not limited thereto.

In another exemplary embodiment, the fourth color light which is delayed fluorescence may be yellow color light or cyan color light, but the embodiment is not limited thereto.

The yellow color light may have a maximum emission wavelength in a range of about 500 nm to about 740 nm, but the embodiment is not limited thereto. The cyan color light may have a maximum emission wavelength in a range of about 445 nm to about 560 nm, but the embodiment is not limited thereto. The magenta color light may have an emission wavelength in a range of about 445 nm to about 485 nm and about 625 nm to about 740 nm, but the embodiment is not limited thereto.

The red color light may have a maximum emission wavelength in a range of about 580 nm to about 700 nm, but the embodiment is not limited thereto. The green color light may have a maximum emission wavelength in a range of about 500 nm to about 600 nm, but the embodiment is not limited thereto. The blue color light may have a maximum emission wavelength in a range of about 400 nm to about 500 nm, but the embodiment is not limited thereto.

In an exemplary embodiment, areas of the first sub-pixel 410, the second sub-pixel 420, the third sub-pixel 430, and the fourth sub-pixel 440 may be identical to or different from each other, but the embodiment is not limited thereto.

In FIG. 4, a structure of the pixel 400 in which the first sub-pixel 410 is disposed adjacent to the second sub-pixel 420 and the third sub-pixel 430, the second sub-pixel 420 is disposed adjacent to the first sub-pixel 410 and the fourth sub-pixel 440, the third sub-pixel 430 is disposed adjacent to the first sub-pixel 410 and the fourth sub-pixel 440, and the fourth sub-pixel 440 is disposed adjacent to the second sub-pixel 420 and the third sub-pixel 430 is illustrated, but the structure is not limited thereto. For example, the pixel 400 may have a structure in which the first sub-pixel 410 and the fourth sub-pixel 440 are disposed adjacent to each other.

In an exemplary embodiment, the pixel 400 may further include a fifth sub-pixel. The fifth sub-pixel may include a fifth emission layer that emits a fifth color light, wherein the fifth color light may be identical to or different from one of the first color light, the second color light, the third color light, and the fourth color light, but the embodiment is not limited thereto.

Hereinabove, the organic light-emitting display device has been described with reference to FIGS. 1 to 4, but the embodiments are not limited thereto.

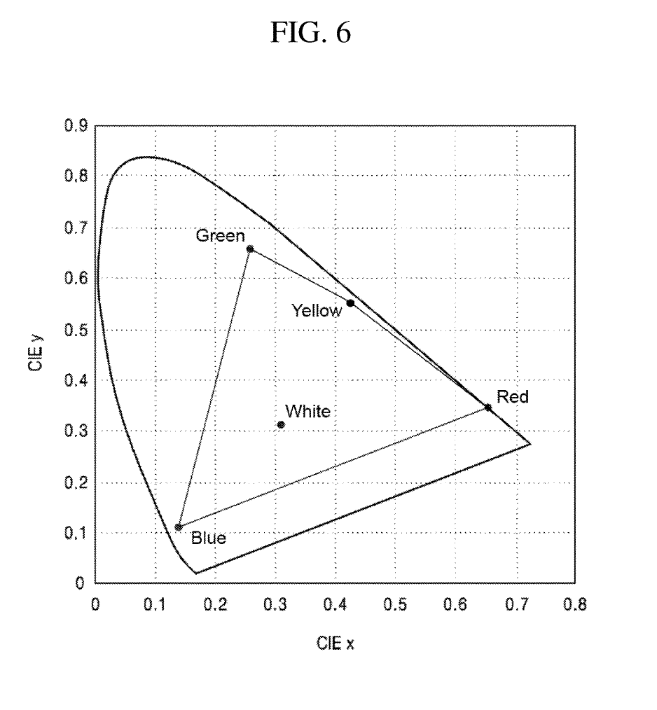

The first color light, the second color light, the third color light, and the fourth color light may form a convex polygon including white color in CIE color coordinates in FIG. 6,

wherein two color lights selected from the first color light, the second color light, the third color light, and the fourth color light may be complementary to each other.

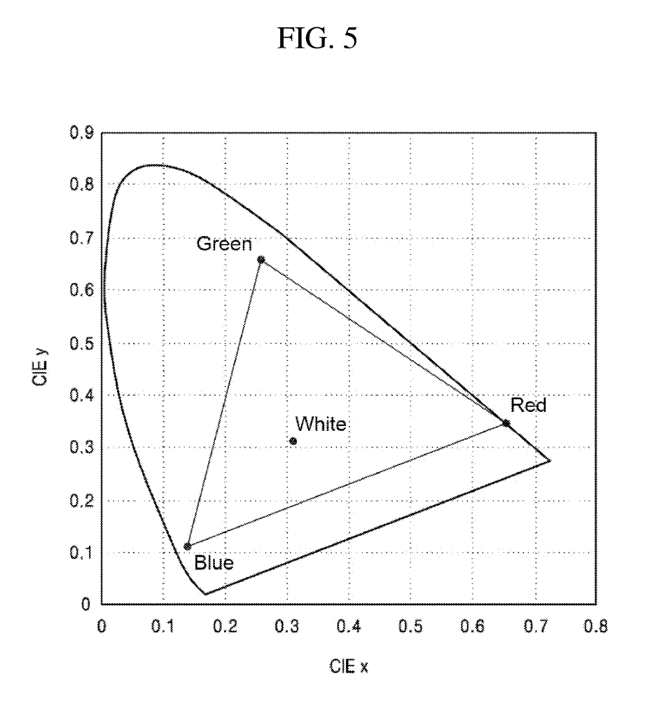

A standard color gamut that represents the color reproduction ranges may be, for example, the National Television System Committee (NTSC) standard. A method of defining a color gamut that is 100% of the NTSC color gamut is described by referring to FIG. 5. FIG. 5 shows CIE color coordinates for each of red, green, and blue, wherein red has CIE color coordinates of x=0.67 and y=0.33, green has CIE color coordinates of x=0.21 and y=0.71, blue has CIE color coordinates of x=0.14 and y=0.08, and white has CIE color coordinates of x=0.31 and y=0.316. In FIG. 5, an area of a triangle produced by given CIE color coordinates of red, green, and blue is defined as 100% of the NTSC color gamut area. Widening the color gamut of the organic light-emitting display device refers that the color gamut of the organic light-emitting display device approaches close to 100% of the NTSC color gamut.

Thus, to widen the color gamut of the organic light-emitting display device, the organic light-emitting display device may further include, in addition to a red sub-pixel, a green sub-pixel, and a blue sub-pixel, a sub-pixel that emits a color outside the gamut defined by red, green, and blue (FIG. 6).

Here, the sub-pixel that emits a color outside the gamut defined by red, green, and blue may emit delayed fluorescence, and accordingly, may provide improved efficiency and long lifespan for the organic light-emitting display device including the sub-pixel described above, as compared with the efficiency of the organic light-emitting display device including a sub-pixel that emits fluorescence only and the lifespan of the organic light-emitting display device including a sub-pixel that emits phosphorescence. Thus, organic light-emitting display device of the embodiments may have high color purity, low power consumption, and long lifespan characteristics.

Hereinafter, an organic light-emitting display device according to an embodiment will be described in detail with Examples.

### EXAMPLES

### Evaluation Example 1

### Measurement of an Energy Gap of Compound CD1

Compound CD1 was subjected to measure a lowest excited singlet energy (E_{S1}) and a lowest excited triplet energy (E_{T1}) as follows. A difference between E_{S1} and E_{T1} was calculated to determine an energy gap ΔST of Compound CD1, and the results are shown in Table 1.

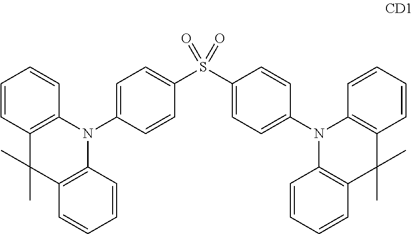 [SMILES: CC1(C)c2ccccc2N(c2ccc(S(=O)(=O)c3ccc(N4c5ccccc5C(C)(C)c5ccccc54)cc3)cc2)c2ccccc21]

(1) Measurement of the lowest excited singlet energy (E_{S1}) of Compound CD1

Compound CD1 was deposited on a Si substrate to a thickness of 100 nm, and then, a fluorescence spectrum thereof was measured at 300K by using a nitrogen laser at a wavelength of 337 nm (MNL200 available from LTB Lasertechnik Berlin GmbH, Berlin, Germany) as a light source and a streak camera (C4334 available from Hamamatsu Photonics K.K., Shizuoka, Japan) as a detector. Here, an x-axis of the fluorescence spectrum represents a wavelength, and a y-axis of the fluorescence spectrum represents emission intensity. A straight line that is the most similar with a graph associated with a short wavelength of the fluorescence spectrum was drawn so that the x-intercept value of the straight line was determined as λ_{edge}. λ_{edge} was then substituted for Equation A to determine E_{S1}.

E_{S1} (eV)=1239.85/_{λedge} <Equation A>

(2) Measurement of the Lowest Excited Triplet Energy (E_{T1}) of Compound CD1

Compound CD1 was deposited on a Si substrate to a thickness of 100 nm, and then, a phosphorescence spectrum thereof was measured at 77K by using a nitrogen laser at a wavelength of 337 nm (MNL200 available from Lasertechnik Berlin company) as a light source and a streak camera (C4334 available from HAMAMATSU company) as a detector. Here, an x-axis of the phosphorescence spectrum represents a wavelength, and a y-axis of the phosphorescence spectrum represents emission intensity. A straight line that is the most similar with a graph associated with a short wavelength of the phosphorescence was drawn so that the x-intercept value of the straight line was determined as λ_{edge}. λ_{edge} was then substituted for Equation B to determine E_{T1}.

E_{T1} (eV)=1239.85/_{λedge} <Equation B>

(3) Calculation of an Energy Gap ΔST of Compound CD1

E_{S1} and E_{T1} obtained in (1) and (2) above substituted for Equation C to determine an energy gap ΔST.

ΔST=E_{T1}−E_{S1} <Equation C>

TABLE 1

| E_{S1} of | E_{T1} of | ΔST of |
|---|---|---|
| Compound CD1 | Compound CD1 | Compound CD1 |
| 2.9 eV | 3.0 eV | 0.1 eV |

### Evaluation Example 2

### Measurement of an Energy Gap of Compound YD1

E_{S1}, E_{T1}, and energy gap ΔST values of Compound YD1 were obtained in the same manner as in Evaluation Example 1, except that Compound CD1 was changed to Compound YD1, and the results are shown in Table 2.

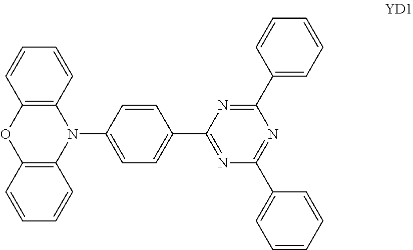 [SMILES: c1ccc(-c2nc(-c3ccccc3)nc(-c3ccc(N4c5ccccc5Oc5ccccc54)cc3)n2)cc1]

TABLE 2

| E_{S1} of | E_{T1} of | ΔST of |
|---|---|---|
| Compound YD1 | Compound YD1 | Compound YD1 |
| 2.3 eV | 2.23 eV | 0.07 eV |

### Example 1

An organic light-emitting display device including a pixel having a configuration as illustrated in FIG. 1 was manufactured as follows.

A TFT was formed on a glass substrate, and a polyimide resin was used to form a planarization film on the TFT. Then, silver (Ag) was patterned on the planarization film to a thickness of 100 nm, and ITO was patterned on the Ag to a thickness of 20 nm, so as to form a first electrode. A polyimide resin was used again to form a pixel-defining layer on the first electrode. The glass substrate was ultrasonically washed with isopropyl alcohol, irradiated by UV light for 30 minutes, cleaned by exposure to ozone, and then, mounted on a vacuum depositor.

Compound HT1 was deposited on the glass substrate to form a hole injection layer (HIL), as a common layer, to a thickness of 75 nm. Compound HT2 was then deposited on the Compound HT1 to form, as common layers, a first sub-pixel HIL to a thickness of 50 nm, a second sub-pixel HIL to a thickness of 30 nm, a third sub-pixel HIL to a thickness of 20 nm, and a fourth sub-pixel HIL to a thickness of 25 nm.

CBP and RD1 were co-deposited on the HIL at a volume ratio of 99:1 to form a first sub-pixel emission layer (i.e., a red emission layer) to a thickness of 60 nm, CBP and GD1 were co-deposited on the HIL at a volume ratio of 92:8 to form a second sub-pixel emission layer (i.e., a green emission layer) to a thickness of 40 nm, BH1 and BD1 were co-deposited on the HIL at a volume ratio of 95:5 to form a third sub-pixel emission layer (i.e., a blue emission layer) to a thickness of 20 nm, and Compound CH1 and Compound CD1 were co-deposited on the HIL at a volume ratio of 95:5 to form a fourth sub-pixel emission layer (i.e., a cyan emission layer) to a thickness of 25 nm.

ET1 was deposited on the emission layer to form, as a common layer, an electron transport layer (ETL) to a thickness of 10 nm. ET2 and Liq were co-deposited on the ETL at a volume ratio of 50:50 to form, as a common layer, an electron injection layer (EIL) to a thickness of 20 nm.

Mg and Ag were co-deposited on the EIL at a volume ratio of 80:20 to form a second electrode to a thickness of 12 nm, thereby completing the manufacture of the organic light-emitting display device.

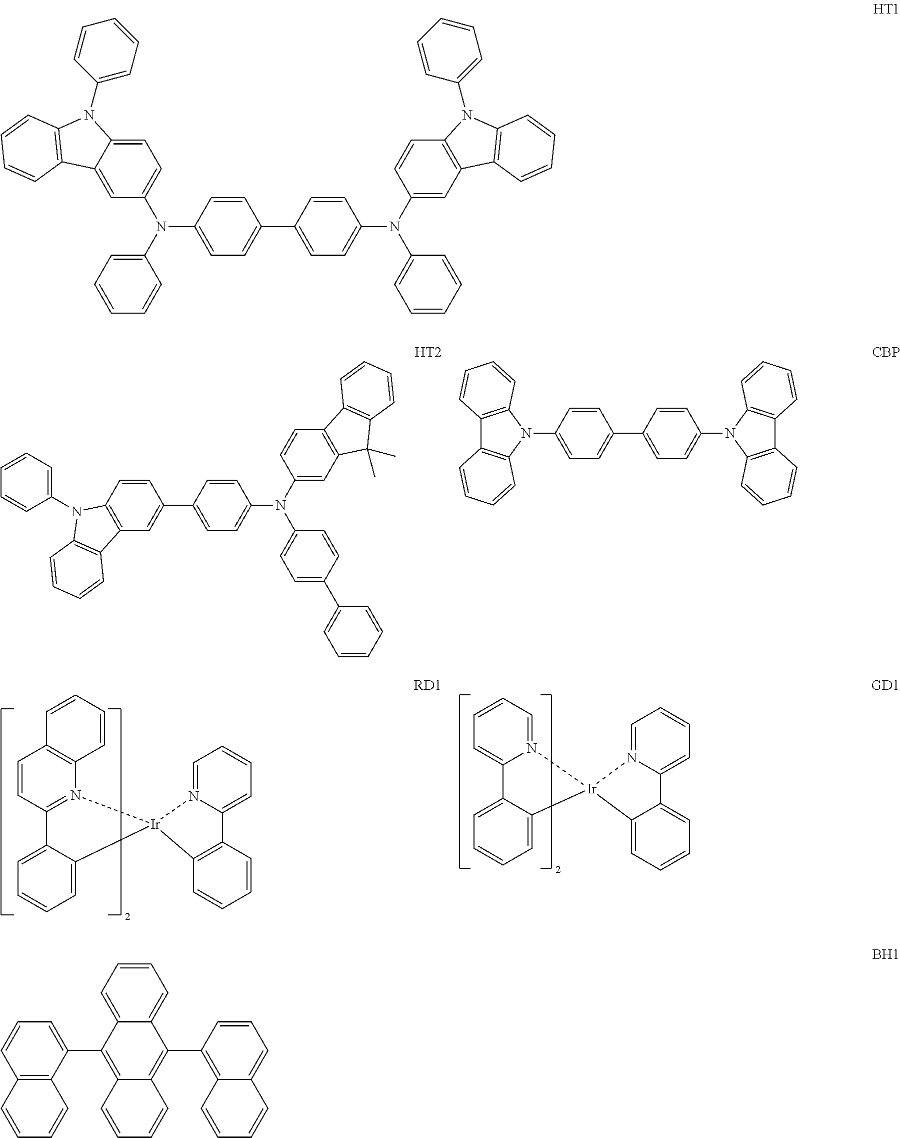

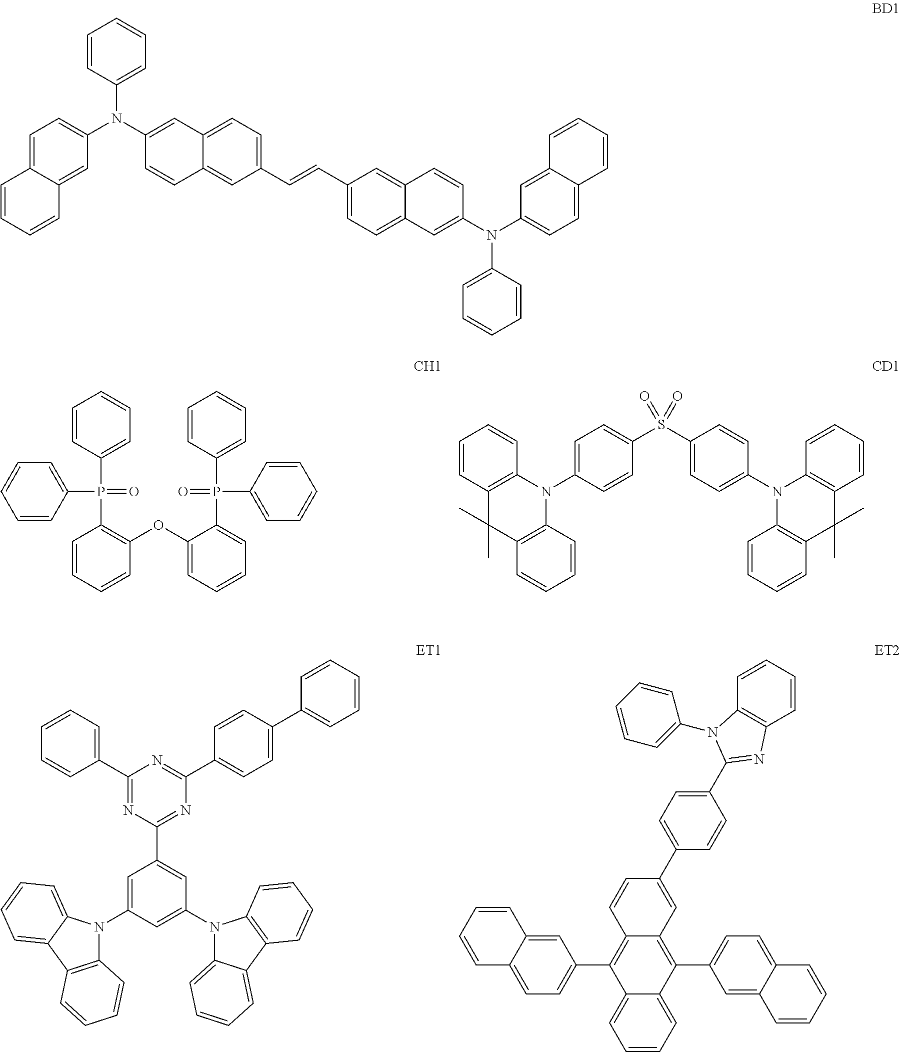 [SMILES: C(=C\c1ccc2cc(N(c3ccccc3)c3ccc4ccccc4c3)ccc2c1)/c1ccc2cc(N(c3ccccc3)c3ccc4ccccc4c3)ccc2c1 ; O=P(c1ccccc1)(c1ccccc1)c1ccccc1Oc1ccccc1P(=O)(c1ccccc1)c1ccccc1 ; CC1(C)c2ccccc2N(c2ccc(S(=O)(=O)c3ccc(N4c5ccccc5C(C)(C)c5ccccc54)cc3)cc2)c2ccccc21 ; c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

### Example 2

An organic light-emitting display device was manufactured in the same manner as in Example 1, except that Compound YH1 and Compound YD1 were used instead of Compound CH1 and Compound CD1, respectively, and that the fourth sub-pixel emission layer (i.e., a yellow emission layer) was formed to a thickness of 50 nm.

### Comparative Example 1

An organic light-emitting display device was manufactured in the same manner as in Example 1, except that the fourth sub-pixel emission layer was not formed.

### Comparative Example 2

An organic light-emitting display device was manufactured in the same manner as in Example 1, except that Compound CBP and Compound FIrpic were used instead of Compound CH1 and Compound CD1, respectively, and that the fourth sub-pixel emission layer (i.e., a cyan emission layer) was formed to a thickness of 25 nm.

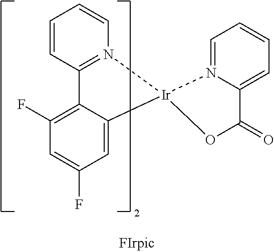

### Example 3

An organic light-emitting display device was manufactured in the same manner as in Example 1, except that Compound ADN and Compound DPAVBi were used instead of Compound CH1 and Compound CD1, and that the fourth sub-pixel emission layer (i.e., a cyan emission layer) was formed to a thickness of 25 nm.

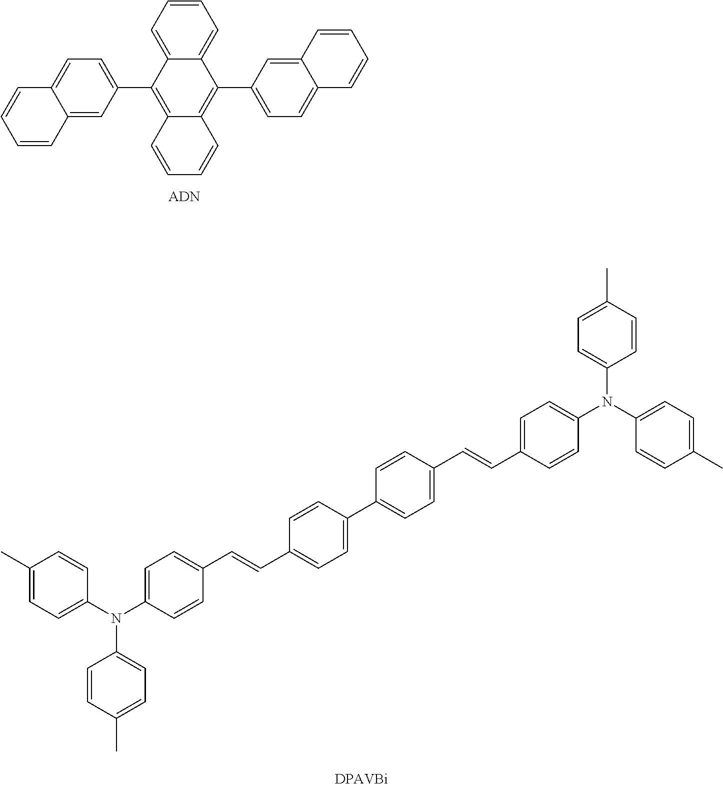

### Evaluation Example 3

The color coordinates and efficiencies of the organic light-emitting display devices of Examples 1 and 2 and Comparative Examples 1 to 3 were measured. In addition, the power consumption and lifespan of the organic light-emitting display devices of Examples 1 and 2 and Comparative Examples 1 to 3 were when white light (0.310, 0.316) at a luminance of 100 cd/m² was emitted. Consequently, the measurement results are shown in Tables 3 to 7 below (where the measurement results of the organic light-emitting display device of Example 1 are shown in Table 3, the measurement results of the organic light-emitting display device of Example 2 are shown in Table 4, the measurement results of the organic light-emitting display device of Comparative Example 1 are shown in Table 5, the measurement results of the organic light-emitting display device of Comparative Example 2 are shown in Table 6, and the measurement results of the organic light-emitting display device of Comparative Example 3 are shown in Table 7). Here, the power consumption was based on an aperture ratio of 50% and a driving voltage of 10 V, and the lifespan results were obtained by measuring the time at which the brightness of the organic light-emitting display devices was 90% of the initial brightness.

TABLE 3

| | Color | | | | | |
|---|---|---|---|---|---|---|
| | coordinates | | Efficiency | 100 nit, NTSC (0.310, 0.316) | | |
| Sub-pixel | CIE_x | CIE_y | (cd/A) | | CIE_x | CIE_y |
| Red | 0.650 | 0.348 | 21.2 | 0.36 | 135 | 140 |
| Green | 0.260 | 0.658 | 32.4 | 0.21 | | |
| Blue | 0.136 | 0.108 | 2.5 | 0.00 | | |
| Cyan | 0.120 | 0.235 | 15.8 | 0.42 | | |

TABLE 4

| | Color | | | | | |
|---|---|---|---|---|---|---|
| | coordinates | | Efficiency | 100 nit, NTSC (0.310, 0.316) | | |
| Sub-pixel | CIE_x | CIE_y | (cd/A) | | CIE_x | CIE_y |
| Red | 0.650 | 0.348 | 21.2 | 0.00 | 249 | 130 |
| Green | 0.260 | 0.658 | 32.4 | 0.15 | | |
| Blue | 0.136 | 0.108 | 2.5 | 0.14 | | |
| Yellow | 0.450 | 0.427 | 21.2 | 0.71 | | |

TABLE 5

| | Color | | | | | |
|---|---|---|---|---|---|---|
| | coordinates | | Efficiency | 100 nit, NTSC (0.310, 0.316) | | |
| Sub-pixel | CIE_x | CIE_y | (cd/A) | | CIE_x | CIE_y |
| Red | 0.650 | 0.348 | 21.2 | 0.30 | 254 | 120 |
| Green | 0.260 | 0.658 | 32.4 | 0.54 | | |
| Blue | 0.136 | 0.108 | 2.5 | 0.16 | | |

TABLE 6

| | Color | | | | | |
|---|---|---|---|---|---|---|
| | coordinates | | Efficiency | 100 nit, NTSC (0.310, 0.316) | | |
| Sub-pixel | CIE_x | CIE_y | (cd/A) | | CIE_x | CIE_y |
| Red | 0.650 | 0.348 | 21.2 | 0.37 | 136 | 5 |
| Green | 0.260 | 0.658 | 32.4 | 0.17 | | |
| Blue | 0.136 | 0.108 | 2.5 | 0.00 | | |
| Cyan | 0.123 | 0.250 | 16.5 | 0.46 | | |

TABLE 7

| | Color | | | | | |
|---|---|---|---|---|---|---|
| | coordinates | | Efficiency | 100 nit, NTSC (0.310, 0.316) | | |
| Sub-pixel | CIE_x | CIE_y | (cd/A) | | CIE_x | CIE_y |
| Red | 0.650 | 0.348 | 21.2 | 0.32 | 179 | 110 |
| Green | 0.260 | 0.658 | 32.4 | 0.23 | | |
| Blue | 0.136 | 0.108 | 2.5 | 0.00 | | |
| Cyan | 0.158 | 0.239 | 10.2 | 0.46 | | |

Referring to Tables 3 to 7, it was confirmed that the organic light-emitting display devices of Examples 1 and 2 had low power consumption and improved lifespan properties, as compared with those of the organic light-emitting display devices of Comparative Examples 1 to 3. In addition, the organic light-emitting display devices of Examples 1 and 2 had excellent color reproducibility, as compared with that of the organic light-emitting display device of Comparative Example 1, based on the fact that the organic light-emitting display devices of Examples 1 and 2 had high-resolution of the NTSC color gamut.

As described above, according to one or more of the above exemplary embodiments, an organic light-emitting display device shows high color purity, low power consumption, and long lifespan characteristics.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims.

What is claimed is:

1. An organic light-emitting display device comprising:
a first sub-pixel, a second sub-pixel, a third sub-pixel, and a fourth sub-pixel,
wherein the first sub-pixel comprises a first emission layer that emits a first color light, the second sub-pixel comprises a second emission layer that emits a second color light, the third sub-pixel comprises a third emission layer that emits a third color light, and the fourth sub-pixel comprises a fourth emission layer that emits a fourth color light;
the first color light, the second color light, the third color light, and the fourth color light emitted are different from each other;
at least one emission layer of the first emission layer, the second emission layer, the third emission layer, and the fourth emission layer emits delayed fluorescence.

2. The organic light-emitting display device of claim 1, wherein the at least one emission layer that emits delayed fluorescence also simultaneously emits fluorescence.

3. The organic light-emitting display device of claim 1, wherein the at least one emission layer that emits delayed fluorescence comprises a host and a dopant, and the dopant has an energy gap ΔST (Dopant) satisfying Equation 1:
ΔST(Dopant)=Eg_{S}(Dopant)−Eg_{T}(Dopant)≦0.3 eV <Equation 1>
wherein in Equation 1, Eg_{S} (Dopant) indicates an excited singlet energy of the dopant, and Eg_{T} (Dopant) indicates an excited triplet energy of the dopant.

4. The organic light-emitting display device of claim 3, wherein the dopant has an energy gap ΔST (Dopant) satisfying Equation 1-1:
0 eV≦ΔST(Dopant)<0.3 eV. <Equation 1-1>

5. The organic light-emitting display device of claim 3, wherein the dopant has an energy gap ΔST (Dopant) satisfying Equation 1-2:
0 eV<ΔST(Dopant)<0.2 eV. <Equation 1-2>

6. The organic light-emitting display device of claim 1, wherein the at least one emission layer that emits delayed fluorescence comprises a host and a dopant, and the host has an energy gap ΔST (Host) satisfying Equation 2:
ΔST(Host)=Eg_{S}(Host)−Eg_{T}(Host)<0.3 eV <Equation 2>
wherein in Equation 2, Eg_{S} (Host) indicates an excited singlet energy of the host, and Eg_{T} (Host) indicates excited triplet energy.

7. The organic light-emitting display device of claim 1, wherein the at least one emission layer that emits delayed fluorescence comprises a host and a dopant, and
at least one of the excited singlet energy of the host and the excited triplet energy of the host is greater than at least one of the excited singlet energy of the dopant and the excited triplet energy of the dopant.

8. The organic light-emitting display device of claim 7, wherein the excited singlet energy of the host, the excited triplet energy of the host, the excited singlet energy of the dopant, and the excited triplet energy of the dopant each independently satisfy one of Equations 2 and 3:
Eg_{S}(Host)>Eg_{S}(Dopant) <Equation 2>
Eg_{T}(Host)>Eg_{T}(Dopant) <Equation 3>
wherein in Equations 2 and 3, Eg_{S} (Host) indicates an excited singlet energy of the host; Eg_{S} (Dopant) indicates an excited singlet energy of the dopant; Eg_{T} (Host) indicates an excited triplet energy of the host; and Eg_{T} (Dopant) indicates an excited triplet energy of the dopant.

9. The organic light-emitting display device of claim 1, wherein the at least one emission layer that emits delayed fluorescence comprises a host and a dopant, and the host is selected from compounds below:

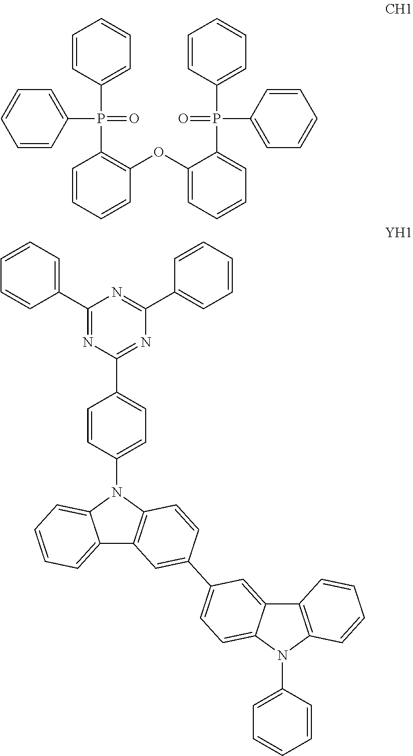

10. The organic light-emitting display device of claim 1, wherein the at least one emission layer that emits delayed fluorescence comprises a host and a dopant, and an amount of the dopant is in a range of about 0.1 vol % to about 50 vol % based on total volumes of the at least one emission layer that emits delayed fluorescence.

11. The organic light-emitting display device of claim 1, wherein the at least one emission layer that emits delayed fluorescence comprises a host and a dopant, and the dopant is selected from compounds below:

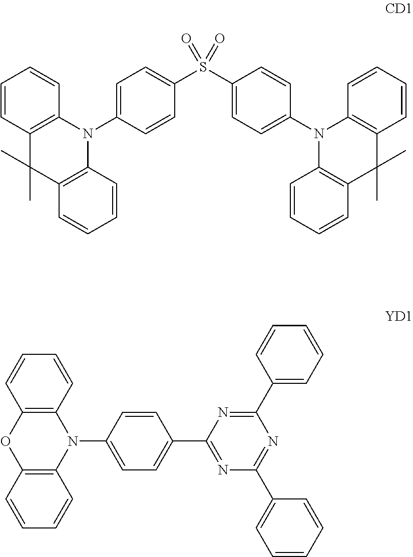 [SMILES: CC1(C)c2ccccc2N(c2ccc(S(=O)(=O)c3ccc(N4c5ccccc5C(C)(C)c5ccccc54)cc3)cc2)c2ccccc21 ; c1ccc(-c2nc(-c3ccccc3)nc(-c3ccc(N4c5ccccc5Oc5ccccc54)cc3)n2)cc1]

12. The organic light-emitting display device of claim 1, wherein the first color light, the second color light, the third color light, and the fourth color light emitted are combined with each other to emit white light.

13. The organic light-emitting display device of claim 1, wherein the first color light emitted is red color light, the second color light emitted is green color light, the third color light emitted is blue color light, and the fourth color light emitted is one selected from yellow color light, cyan color light, and magenta color light.

14. The organic light-emitting display device of claim 1, wherein the fourth color light emitted is yellow color light or cyan color light.

15. The organic light-emitting display device of claim 1, wherein the fourth color light emitted in delayed fluorescence is yellow color light, cyan color light, or magenta color light.

16. The organic light-emitting display device of claim 1, wherein the fourth color light emitted in delayed fluorescence is yellow color light or cyan color light.

17. The organic light-emitting display device of claim 1, wherein a maximum emission wavelength of the yellow color light is in a range of about 500 nm to about 740 nm;
a maximum emission wavelength of the cyano color light is in a range of about 445 nm to about 560 nm; and
an emission wavelength of the magenta color light is in a range of about 445 nm to about 485 nm and in a range of about 625 nm to about 740 nm.

18. The organic light-emitting display device of claim 1, wherein areas of the first sub-pixel, the second sub-pixel, the third sub-pixel, and the fourth sub-pixel are identical to or different from each other.

19. The organic light-emitting display device of claim 1 further comprising a fifth sub-pixel, wherein the fifth sub-pixel comprises a fifth emission layer that emits a fifth color light, and
the fifth color light is identical to or different from one of the first color light, the second color light, and third color light, and the fourth color light.

20. The organic light-emitting display device of claim 1, wherein the first sub-pixel, the second sub-pixel, the third sub-pixel, and the fourth sub-pixel are disposed in a stripe type, a rectangular type, or a pentile type.
